(19) United States
(12) Patent Application Publication
(10) Pub. No.: US 2026/0064916 A1
(43) Pub. Date: Mar. 5, 2026

(54) MEDICAL PROCEDURE SIMULATION WITH AN ARTIFICIAL INTELLIGENCE MENTOR

(71) Applicant: Intuitive Surgical Operations, Inc., Sunnyvale, CA (US)

(72) Inventors: Alec Moore, Santa Clara, CA (US); David Pearl, Mountain View, CA (US); Robert G. Stricko, III, Sunnyvale, CA (US)

(73) Assignee: Intuitive Surgical Operations, Inc., Sunnyvale, CA (US)

(21) Appl. No.: 19/052,005

(22) Filed: Feb. 12, 2025

Related U.S. Application Data
(60) Provisional application No. 63/690,160, filed on Sep. 3, 2024.

(51) Int. Cl. G06F 30/27

(52) U.S. Cl. CPC G06F 30/27

(57) ABSTRACT

Medical procedure simulation with artificial intelligence mentors is described. One or more processors can construct an artificial intelligence agent using data of medical procedures performed by at least one medical practitioner, the artificial intelligence agent to perform a simulated medical procedure on a three dimensional anatomical structure. The one or more processors can animate, on a user interface, at least one action of the artificial intelligence agent in a simulated medical environment to perform the simulated medical procedure on the three dimensional anatomical structure. The one or more processors can receive an input from a medical robotic system to manipulate an instrument in the simulated medical environment. The one or more processors can animate movement of the instrument within the simulated medical environment based on the input received from the medical robotic system.

### CROSS-REFERENCE TO RELATED PATENT APPLICATION

This application claims the benefit of priority under 35 U.S.C. § 119 to U.S. Provisional Patent Application No. 63/690,160, filed on Sep. 3, 2024, which is hereby incorporated by reference herein in its entirety for all purposes.

### BACKGROUND

A medical robotic system can include an instrument for performing a medical session or procedure. For example, the instrument can be used to perform surgery, therapy, or a medical evaluation. The medical robotic system can include an endoscope that captures a video of the medical procedure.

### SUMMARY

Technical solutions disclosed herein can include a computing system to implement medical procedure simulations to enhance skill development for medical practitioners through dynamic, data-driven simulations. The computing system can collect and analyze practitioner data to tailor personalized learning pathways and training exercises in a simulated environment. Additionally, the system can construct artificial intelligence (AI) mentors modeled on expert surgeon data. The AI mentor autonomously perform medical procedures in simulated environments, offering guidance and suggestions to medical practitioners during practice sessions. Furthermore, the system can implement a generative model to answer user queries about the simulated environment or other medical procedure videos. The computing system can maintain a multi-modal knowledgebase to provide contextual data that can be used by the generative model to provide responses to the user queries.

At least one aspect of the present disclosure is directed to a system. The system can include one or more processors, coupled with memory, to construct an artificial intelligence agent using data of medical procedures performed by at least one medical practitioner, the artificial intelligence agent to perform a simulated medical procedure on a three dimensional anatomical structure. The one or more processors can animate, on a user interface, at least one action of the artificial intelligence agent in a simulated medical environment to perform the simulated medical procedure on the three dimensional anatomical structure. The one or more processors can receive an input from a medical robotic system to manipulate an instrument in the simulated medical environment. The one or more processors can animate, on the user interface with the animated at least one action, movement of the instrument within the simulated medical environment based on the input received from the medical robotic system.

The one or more processors can receive historical performance indicators of an operator of the medical robotic system. The one or more processors can generate a training pathway for the operator using the historical performance indicators, the training pathway comprising a series of tasks for the operator to perform in simulations. The one or more processors can identify a task of the series of tasks for the operator to perform. The one or more processors can generate an interactive simulation for the operator of the medical robotic system to perform to complete the task.

The one or more processors can train at least one model of the artificial intelligence agent using at least one machine learning technique and the data of the medical procedures performed by the at least one medical practitioner, the model to determine the at least one action. The one or more processors can receive data describing the three dimensional anatomical structure. The one or more processors can execute the model of the artificial intelligence agent using the data describing the three dimensional anatomical structure to determine the at least one action.

The one or more processors can receive data indicating movement of an eye of the at least one medical practitioner during at least one medical procedure. The one or more processors can generate, using the data indicating movement of the eye of the at least one medical practitioner, a heatmap comprising a plurality of points and corresponding levels, the corresponding levels indicating lengths of time the medical practitioner looked at the plurality of points. The one or more processors can receive data indicating movement of an eye of an operator of the medical robotic system. The one or more processors can cause the user interface to display the heatmap and the movement of eye of the operator on the heatmap.

The one or more processors can generate at least one performance metric based on the data of the at least one medical practitioner. The one or more processors can generate, based on the input received from the medical robotic system, at least one performance metric for an operator of the medical robotic system. The one or more processors can cause the user interface to display data based on a comparison of the at least one performance metric of the at least one medical practitioner to the at least one performance metric of the operator.

The one or more processors can receive performance results of a plurality of simulated medical procedures of a plurality of different types performed by an operator of the medical robotic system. The one or more processors can identify, based on the performance results, a performance issue for a type of medical procedure of the plurality of different types of medical procedures. The one or more processors can generate the medical environment and the three dimensional anatomical structure based on the performance issue.

The one or more processors can generate pseudo-random values for a plurality of attributes defining the three dimensional anatomical structure. The one or more processors can generate the three dimensional anatomical structure based on the pseudo-random values for the plurality of attributes.

The one or more processors can receive user defined values via the user interface for a plurality of attributes defining the three dimensional anatomical structure. The one or more processors can generate the three dimensional anatomical structure based on the user defined values for the plurality of attributes.

The one or more processors can receive a three dimensional scan of a physical anatomical structure. The one or more processors can generate the three dimensional anatomical structure based on the three dimensional scan.

The one or more processors can receive, via the user interface, a selection of an entire medical procedure to simulate, or a portion of the medical procedure to simulate. The one or more processors can simulate the medical procedure based on the selection.

The one or more processors can receive a query about the simulated medical procedure from a client device. The one or more processors can retrieve, using the query, one or more resources on medical procedures from a data repository. The one or more processors can construct a prompt based on the query, the simulated medical procedure, and the one or more resources. The one or more processors can provide the prompt to a generative model to generate a response to the query, the response comprising a citation to a resource of the one or more resources. The one or more processors can transmit the response to the client device.

The one or more processors can execute a generative model to predict a plurality of queries comprising questions users are likely to ask during the simulated medical procedure. The one or more processors can retrieve, using the queries, portions of resources on the medical procedures from a data repository. The one or more processors can execute the generative model using the queries, the simulated medical procedure, and the portions of the resources to generate responses to the queries, the responses comprising citations to the resources. The one or more processors can transmit the queries and the responses to a client device to display in a graphical user interface on the client device.

At least one aspect of the present disclosure is directed to a method. The method can include constructing, by one or more processors, coupled with memory, an artificial intelligence agent using data of medical procedures performed by at least one medical practitioner, the artificial intelligence agent to perform a simulated medical procedure on a three dimensional anatomical structure. The method can include animating, by the one or more processors, on a user interface, at least one action of the artificial intelligence agent in a simulated medical environment to perform the simulated medical procedure on the three dimensional anatomical structure. The method can include receiving, by the one or more processors, an input from a medical robotic system to manipulate an instrument in the simulated medical environment. The method can include animating, by the one or more processors, on the user interface with the animated at least one action, movement of the instrument within the simulated medical environment based on the input received from the medical robotic system.

The method can include receiving, by the one or more processors, historical performance indicators of an operator of the medical robotic system. The method can include generating, by the one or more processors, a training pathway for the operator using the historical performance indicators, the training pathway comprising a series of tasks for the operator to perform in simulations. The method can include identifying, by the one or more processors, a task of the series of tasks for the operator to perform. The method can include generating, by the one or more processors, an interactive simulation for the operator of the medical robotic system to perform to complete the task.

The method can include training, by the one or more processors, at least one model of the artificial intelligence agent using at least one machine learning technique and the data of the medical procedures performed by the at least one medical practitioner, the model to determine the at least one action. The method can include receiving, by the one or more processors, data describing the three dimensional anatomical structure. The method can include executing, by the one or more processors, the model of the artificial intelligence agent using the data describing the three dimensional anatomical structure to determine the at least one action.

The method can include receiving, by the one or more processors, data indicating movement of an eye of the at least one medical practitioner during at least one medical procedure. The method can include generating, by the one or more processors, using the data indicating movement of the eye of the at least one medical practitioner, a heatmap comprising a plurality of points and corresponding levels, the corresponding levels indicating lengths of time the medical practitioner looked at the plurality of points. The method can include receiving, by the one or more processors, data indicating movement of an eye of an operator of the medical robotic system. The method can include causing, by the one or more processors, the user interface to display the heatmap and the movement of eye of the operator on the heatmap.

The method can include generating, by the one or more processors, at least one performance metric based on the data of the at least one medical practitioner. The method can include generating, by the one or more processors, based on the input received from the medical robotic system, at least one performance metric for an operator of the medical robotic system. The method can include causing, by the one or more processors, the user interface to display data based on a comparison of the at least one performance metric of the at least one medical practitioner to the at least one performance metric of the operator.

The method can include receiving, by the one or more processors, performance results of a plurality of simulated medical procedures of a plurality of different types performed by an operator of the medical robotic system. The method can include identifying, by the one or more processors, based on the performance results, a performance issue for a type of medical procedure of the plurality of different types of medical procedures. The method can include generating, by the one or more processors, the medical environment and the three dimensional anatomical structure based on the performance issue.

At least one aspect of the present disclosure is directed to a non-transitory computer-readable medium storing processor-executable instructions that, when executed by one or more processors, cause the one or more processors to construct an artificial intelligence agent using data of medical practitioners performed by at least one medical practitioner, the artificial intelligence agent to perform a simulated medical procedure on a three dimensional anatomical structure. The one or more processors can animate, on a user interface, at least one action of the artificial intelligence agent in a simulated medical environment to perform the simulated medical procedure on the three dimensional anatomical structure. The one or more processors can receive an input from a medical robotic system to manipulate an instrument in the simulated medical environment. The one or more processors can animate, on the user interface with the animated at least one action, movement of the instrument within the simulated medical environment based on the input received from the medical robotic system.

The one or more processors can receive data indicating movement of an eye of the at least one medical practitioner during at least one medical procedure. The one or more processors can generate, using the data indicating movement of the eye of the at least one medical practitioner, a heatmap comprising a plurality of points and corresponding levels, the corresponding levels indicating lengths of time the medical practitioner looked at the plurality of points. The one or more processors can receive data indicating movement of an eye of an operator of the medical robotic system. The one or more processors can cause the user interface to display the heatmap and the movement of eye of the operator on the heatmap.

Technical solutions disclosed herein can also include a computing system that uses a generative model to answer queries, such as spoken or typed user questions, on medical procedure videos. The computing system can aggregate data for the generative model to reference, i.e., implement a multi-media data ingestion pipeline for creating a reference knowledgebase. The knowledgebase can be augmented to store chunked or embedded data that the generative model can use when generating responses. For example, the knowledgebase can store medical resources (e.g., medical literature, clinical reports or studies, or medical papers), historical videos of medical procedures captured by a medical robotic system (e.g., captured by a camera or endoscope of the medical robotic system), and kinematics data collected by the medical robotic system when performing the medical procedure, for example, force, torque, acceleration, or velocity data of links, arms, appendages, or manipulators of the medical robotic system. With the augmented knowledgebase, the computing system can embed a query and use the query embedding to retrieve context from the knowledgebase helpful in answering the question posed by the query. The computing system can execute the generative model to output or produce a response based at least in part on the query, the retrieved context, and the video that the user is asking the question regarding. The generative model can generate the response to include a citation to the medical literature that supports or evidences the response generated by the generative model.

At least one aspect of the present disclosure is directed to a system. The system can include one or more processors, coupled with memory, to receive a query about a video of a medical procedure from a client device. The one or more processors can retrieve, using the query, one or more resources on medical procedures from a data repository. The one or more processors can construct a prompt based on the query, the video, and the one or more resources. The one or more processors can provide the prompt to a generative model to generate a response to the query, the response including a citation to a resource of the one or more resources. The one or more processors can transmit the response to the client device.

The prompt can include the video. The one or more processors can receive resources including data of clinical studies. The one or more processors can generate chunks from the resources. The one or more processors can generate embeddings from the chunks using an embedding model. The one or more processors can store the embeddings in the data repository.

The one or more processors can receive, from medical robotic systems, videos of medical procedures and kinematics data of the medical procedures. The one or more processors can generate embeddings of the videos and the kinematics data. The one or more processors can augment the data repository to store the embeddings of the videos and the kinematics data.

The one or more processors can analyze the response and the citation to determine whether the response is a hallucinated response. The one or more processors can suppress the response responsive to a determination that the response is the hallucinated response.

The one or more processors can determine a confidence level of the response based at least in part on the citation. The one or more processors can transmit the confidence level with the response to the client device to display within a graphical user interface on the client device.

The one or more processors can receive kinematics data of the medical procedure from a medical robotic system that performed at least a portion of the medical procedure. The one or more processors can execute the generative model using the kinematics data to generate the response.

The one or more processors can execute the generative model to predict queries including questions users are likely to ask at times while watching the video of the medical procedure. The one or more processors can predict or identify videos of similar cases to those shown, this can expand clinician learning outside of a given instance of a case, and allow a clinician to learn holistically. The one or more processors can retrieve, using the queries, portions of resources on the medical procedures from the data repository. The one or more processors can execute the generative model using the queries, the video, and the portions of the resources to generate responses to the queries, the responses including citations to the resources. The one or more processors can transmit the queries and the responses to the client device to display in a graphical user interface on the client device responsive to a play time of the video reaching the times.

The one or more processors can input the response to a second generative model configured to establish a guardrail. The one or more processors can determine, based on an output from the second generative model generated using the response, that the response satisfies the guardrail. The one or more processors can transmit the response to the client device responsive to the determination that the response satisfies the guardrail.

The data repository can include a set of multi-modal embeddings of resources, videos of medical procedures, kinematics data, or logging data of a medical robotic system that performed the medical procedures.

The generative model can include at least one of a large language model, a small language model, or a world model.

The one or more processors can receive the query, the query including unstructured text related to an event in the medical procedure of the video. The event can include an external collision.

The one or more processors can receive the query from the client device, the query asking what types of medical procedure errors are likely to occur during the medical procedure. The one or more processors can execute the generative model using the query to generate the response including a prediction of the medical procedure errors that are likely to occur in the medical procedure.

The one or more processors can determine a timestamp corresponding to receipt of the query from the client device. The one or more processors can map the timestamp to a second timestamp in the video. The one or more processors can construct, based on the query, the prompt to prevent the generative model from accessing frames of the video subsequent to the second timestamp to generate the response.

The one or more processors can generate a video clip with frames of the video with timestamps that are less than or equal to the second timestamp, the video clip excluding frames of the video that are subsequent to the second timestamp. The one or more processors can construct the prompt including the video clip.

At least one aspect of the present disclosure is directed to a method. The method can include receiving, by one or more processors, coupled with memory, a query about a video of a medical procedure from a client device. The method can include retrieving, by the one or more processors, using the query, one or more resources on medical procedures from a data repository. The method can include constructing, by the one or more processors, a prompt based on the query, the video, and the one or more resources. The method can include providing, by the one or more processors, the prompt to a generative model to generate a response to the query, the response including a citation to a resource of the one or more resources. The method can include transmitting, by the one or more processors, the response to the client device.

The method can include analyzing, by the one or more processors, the response and the citation to determine whether the response is a hallucinated response. The method can include suppressing, by the one or more processors, the response responsive to a determination that the response is the hallucinated response.

At least one aspect of the present disclosure is directed to one or more storage media storing instructions thereon, that, when executed by one or more processors, cause the one or more processors to perform operations, including receiving a query about a video of a medical procedure from a client device. The operations can include retrieving, using the query, one or more resources on medical procedures from a data repository. The operations can include constructing a prompt based on the query, the video, and the one or more resources. The operations can include providing the prompt to a generative model to generate a response to the query, the response including a citation to a resource of the one or more resources. The operations can include transmitting the response to the client device.

The data repository can include a set of multi-modal embeddings of resources, videos of medical procedures, and kinematics data of a medical robotic system that performed the medical procedures.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 depicts an example computing system to process queries on a medical procedure video using a generative model.

FIG. 2 depicts an example method of generating responses to medical procedure video queries using a generative model.

FIG. 3 is an example graphical user interface including a video player and an input for a user to submit a query.

FIG. 4 depicts an example computing system to simulate a medical procedure, the simulation including an AI mentor.

FIG. 5 depicts an example method of simulating a medical procedure, the simulation including an AI mentor.

FIG. 6 depicts an example computing architecture of a computing system.

### DETAILED DESCRIPTION

Following below are more detailed descriptions of various concepts related to, and implementations of, methods, apparatuses, and systems to simulate medical procedures with an AI mentor and/or to process queries on a medical procedure video using a generative model. The various concepts introduced above and discussed in greater detail below may be implemented in any of numerous ways.

This disclosure is generally directed to a medical robotic system, or a simulator for such a system. The medical robotic system can be used to perform or simulate at least a portion of a medical procedure, such as a surgery, a therapy, or a medical evaluation. Existing clinical training systems can be largely reliant on static, third-party courses that do not cater to individual learning needs or evolving surgical techniques. These traditional methods may not simulate real-world environments. Furthermore, the training methods may not be able to personalize training based on a clinicians strengths and areas for improvement. The training methods may also offer a limited set of static training activities. Furthermore, the training methods may not provide comparative analysis of the clinician's performance against leading experts in the field.

Furthermore, when clinicians watch procedure videos to learn procedure techniques, they do not have a way to get questions answered that are relevant to the procedure videos they are watching. Watching procedure videos may not be an interactive experience for the medical practitioner, as the information may only be unidirectional, i.e., the medical practitioner views the video. There may be no opportunity for a viewer to get real-time answers to questions about the subject or contextual interactions within a video, e.g., a bidirectional share of information. The virtual case observations may be limited in their opportunities for access. For a clinician to be able to provide real-time answers, viewers have to be signed on and watching the case in real-time, while the actual procedure is occurring. A medical practitioner can ask virtual case observation cases to an expert clinical, but the clinician is limited to answering the questions with the clinician's own individual experience. Additionally, even with real-time case observations, learners are limited to asking the teacher questions about the case, but are not afforded the ability to perform the actions they are learning themselves.

A generative artificial intelligence (GAI) model, such as a large language model (LLM), can be used to respond to questions that a clinician asks. However, there are one or more technical challenges with implementing a generative model to respond to questions about a medical procedure video. For example, the generative model may respond with hallucinated information, e.g., assert medical facts, suggestions, recommendations, or conclusions that are false but are written by the generative model in a manner that appears rational, or convincing to the reader. Hallucinated responses can be responses that a generative model asserts and appear reasonable or valid, but are not factually or technically accurate. In some cases, the generative model can be trained on medical information or be trained to avoid hallucinations. However, retraining a generative model can be time consuming, costly, and require excess computational or memory resources. Furthermore, if the underlying medical truth data changes, e.g., new medical discoveries are learned, new medical procedures are developed, old medical procedures are discarded, the generative model may not be current, and the responses that the generative model provides may not reflect advances in medical knowledge, unless the generative model is periodically retrained on newly collected medical information (which can be time consuming, and use excess computational and memory resources).

To solve these, and other technical problems, technical solutions of this disclosure can include a computing system to implement medical procedure simulation with an AI mentor. The computing system can implement a dynamic simulation system to enhance clinical skill development, particularly for medical practitioners. The simulations can be data-drive, and thus flexible and dynamic to provide a medical practitioner training to learn new skills and develop. The computing system can provide an interactive simulation allowing a user to provide input (e.g., via a medical robotic system) to control virtual instruments in the interactive simulation environment to perform a procedure on a simulated anatomical structure. The computing system can collect and analyze medical practitioner data over time, and tailor a learning pathway or series of training exercises to be performed in a simulated environment for each medical practitioner. The computing system can provide personalized, real-time, and adjustable training environments by leveraging dynamic anatomical models, real patient data, and surgeon performance history. This allows clinicians to practice specific skills or full procedures, with the computing system identifying strengths and weaknesses through continuous observation and comparison to industry leaders.

Furthermore, the computing system can construct AI mentors. The AI mentors can be agent based medical practitioners that can autonomously perform a medical procedure in a simulated environment. The AI mentors can be modeled on the performance and techniques of key opinion leaders or expert surgeons. The computing system can animate the actions of the AI mentor within the simulated environment to provide training or suggestions to a medical practitioner. The AI mentor can offer guidance to a medical practitioner during a simulated practice sessions as if a leading surgeon were present.

Furthermore, technical solutions of this disclosure can include a computing system that uses a generative model to answer queries, such as spoken or typed user questions, on medical procedure videos. The computing system can respond to user queries asking questions about a video of a medical procedure using a generative model. For example, a computing system can maintain a multi-modal knowledgebase, such as a vector database, that stores contextual information that the generative model can use to answer the user queries. The computing system can implement retrieval-augmented generation (RAG) to generate responses to the user questions that are reliable, e.g., are not hallucinated responses. The generative model can be an LLM, a small language model (SLM), a world model, or any other type of generative AI model, algorithm, or technique. This can bridge the gap between procedure videos and virtual case observations by automating the question answering process on behalf of the performing clinician, so that it can be performed at any time for a viewer who does not have to be watching the case in real-time.

The computing system can aggregate data for the generative model to reference, i.e., implement a multi-media data ingestion pipeline for creating a reference knowledgebase that includes tagging and scoring of quality and relevance for different procedures. The knowledgebase can be augmented to store chunked or embedded data that the generative model can use when generating responses. For example, the knowledgebase can store medical resources, such as medical literature, clinical reports or studies, or medical papers. Furthermore, the knowledgebase can store historical videos of medical procedures captured by a medical robotic system, e.g., captured by a camera or endoscope of the medical robotic system. Furthermore, the knowledgebase can store kinematics data collected by the medical robotic system when performing the medical procedure, for example, force, torque, acceleration, or velocity data of links, arms, appendages, or manipulators of the medical robotic system. The knowledgebase can allow a generative model to be informed by data from a wide body of expertise across a global population of clinicians instead of a single individual, reducing the likelihood of biased, misinformed, or out-of-date responses.

With the augmented knowledgebase, the computing system can embed a query and use the query embedding to retrieve context from the knowledgebase helpful in answering the question posed by the query. The computing system can execute the generative model to output or produce a response based at least in part on the query, the retrieved context, and the video that the user is asking the question regarding. The generative model can generate the response to include a citation to the medical literature that supports or evidences the response generated by the generative model. The computing system can further implement a guardrail system, that determines the reliability or confidence in the response produced by the generative model and the presence or weight of the asserted authority, to determine whether the response produced by the large language model is hallucinated or not. The computing system can suppress or determine not to respond to the query responsive to determining that the response is hallucinated. The guardrail system can reduce the possibility of hallucinated responses, i.e., those that are not grounded in the knowledgebase.

By using data inputs (e.g., video, audio, kinematic, etc.) from the subject video and a body of data that is relevant to the field of robotic surgery (e.g., medical publications, medical papers, medical research results, other medical procedure videos, kinematics data of other medical procedures, etc.), a prompt can be generated to input into the generative model, real-time responses to questions can be generated and provided to clinicians, aiding in their learning. The generative model implementation can provide simulated remote case observation and proctoring through generative model enhanced surgical procedure recordings. The generative model can provide contextual responses to questions to convert recordings into time-flexible virtual case observation experiences, creating more easily accessible and higher quality learning opportunities. Furthermore, with the multi-modal data collected by the computing system, the computing system can simulate surgical or medical procedures. The computing system can utilize generative models to answer questions regarding the simulated procedures.

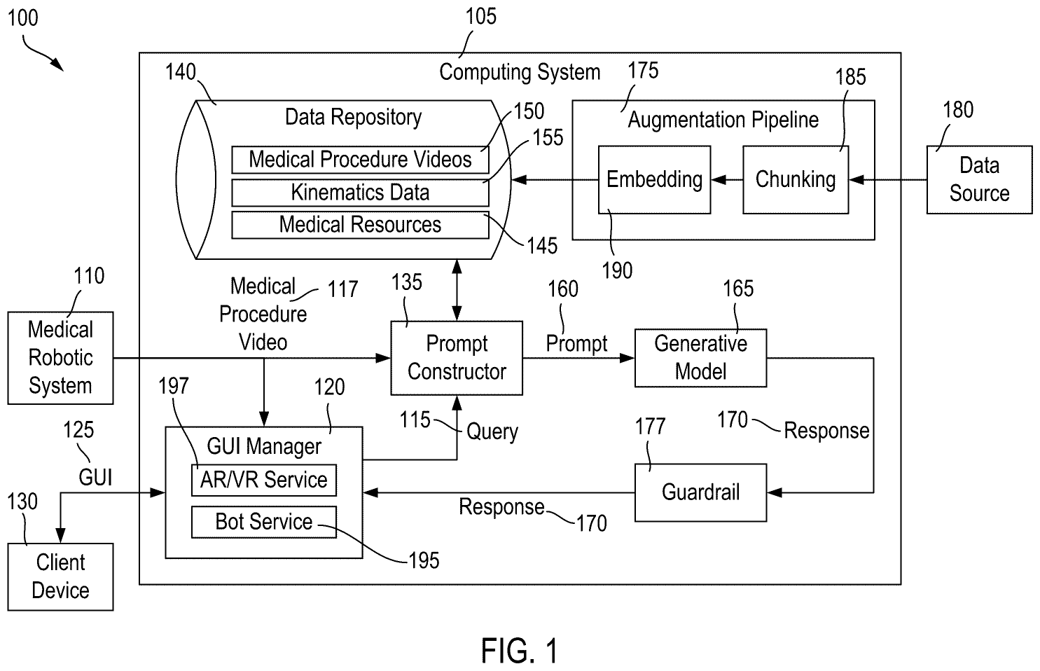

Referring now to FIG. 1, among others, a system 100 including a computing system 105 to implement a generative model 165 with medical procedure video queries 115 is shown. The system 100 can include at least one computing system 105. The computing system 105 can be a data processing system, a computing system, a computer system, a computer, a desktop computer, a laptop computer, a tablet, a control system, a console system, an embedded system, a cloud computing system, a server system, or any other type of computing system. The computing system 105 can be an on-premises system or an off-premises system. The computing system 105 can be a hybrid system, where some components of the computing system 105 are located on-premises, and some components of the computing system 105 are located off-premises.

The system 100 can include at least one medical robotic system 110. The medical robotic system 110 can be a robotic system, apparatus, or assembly including at least one instrument. The instrument can be or include a tip or end. The tip or end can be installed with or to the instrument. The tip can be removable or a permanent component of the instrument or the medical robotic system 110. For example, the tip can be a scalpel, a scissors, a monopolar curved scissors (MCS), a cautery hook tip, a cautery spatula tip, a needle driver, a forceps, a round tooth retractor, a drill, or a clip applier. The instrument can be or include a robotic arm, a robotic appendage, a robotic snake, or any other motor-controlled member that can be articulated by the medical robotic system 110. The instrument can include at least one actuator, such as a motor, servo, or other actuator device. The instrument can be manipulated by motors, servos, actuators, or other devices to perform a medical procedure. The medical robotic system 110 can perform a medical session or medical procedure. For example, the medical robotic system 110 can articulate the instrument to perform surgery, therapy, or a medical evaluation with the instrument. The medical procedure can be performed on a subject, e.g., a human, an adult, a child, or an animal. A medical practitioner, such as a surgeon, technician, nurse, or other operator can provide input via a user device or input apparatus (e.g., joystick, buttons, touchpad, keyboard, steering apparatus, etc.) to manipulate the instrument to perform a medical procedure. The medical robotic system 110 can include an endoscope, in some implementations. The endoscope can be an instrument that is manipulated by the medical practitioner and controlled via a motor, servo, or other input device.

The computing system 105 can receive data of a medical procedure performed on a subject with the medical robotic system 110. The computing system 105 can receive at least one image frame or medical procedure video 117 from the medical robotic system 110. The medical procedure video 117 can be an endoscopic video captured by an endoscope. The medical procedure video 117 can be a stereoscopic video or a monocular video. For example, the medical procedure videos 117 can be or include at least one or a set of frames that are two dimensional (2D) or three dimensional (3D) images. The medical procedure videos 117 can be or include at least one depth map. The depth maps that indicate a 3D character of the various objects, patients, or instruments in the images. The medical procedure video 117 can include frames or images of at least one anatomical structure of a patient (e.g., human, animal, or biological material) during a medical procedure. The procedure video 117 can include images of a medical procedure is a polypectomy, cataract surgery, caesarean section, appendectomy, or any other type of medical procedure, surgical procedure, or procedure. The computing system 105 can implement background noise minimization, cleaning, or filtering. If the medical procedure video 117 includes a recorded audio track where a doctor, nurse, or other medical practitioner narrates the procedure or makes comments or statements during the procedure, the computing system 105 can implement audio to text translation, implement language translation (e.g., translate the spoken language to English), or any other pre-processing steps.

In addition to receiving the video 117 from the medical robotic system 110, the computing system 105 can receive kinematics data or recorded system data, e.g., number of pedal counts, power consumed by the medical robotic system 110, number of clutches of the medical robotic system 110, etc. The kinematics data or recorded system can be used along with the video 117 for executing the generative model 165. By including the kinematics data and the recorded system data in addition to the video 117, more context can be available to the generative model 165 for generating a response 170.

The computing system 105 can include at least one graphical user interface (GUI) manager 120. The GUI manager 120 can generate at least on GUI 125. The GUI 125 can be an interface for a user, such as a medical practitioner, to interact with the generative model 165. The GUI manager 120 can generate, construct, or produce the GUI 125. The GUI manager 120 can cause at least one client device 130 to render or display the GUI 125. The client device 130 can be or include a console for a medical practitioner, a smartphone, a laptop computer, a desktop computer, a tablet computer, etc. The client device 130 can be integrated with, or be a part of, the medical robotic system 110. The client device 130 can include a display device, such as an LED, LCD, OLED, etc. to display the responses 170 to the medical practitioner. The client device 130 can include a keyboard, hand controls, digital pointers, microphone-based voice input, or other input device for receiving the query 115 from a medical practitioner or otherwise interacting with the generative model 165. The client device 130 can include a speaker for playing the response 170 to the medical practitioner.

The client device 130 can display output to a medical practitioner (e.g., the GUI 125, a response 170, the response 170 within the GUI 125, the query 115, a chat interface, etc.). The GUI 125 can allow a user to view or explore reference media (e.g., medical procedure videos 150, kinematics data 155, or medical resources 145 used in a prompt 160 to produce a response 170), provide feedback on the quality of the responses 170, and view new media (such as a recording or live feed of a procedure).

The computing system 105 can receive at least one query 115 from at least one client device 130. The medical practitioner can provide at least one query 115 to the computing system 105 via the client device 130. The medical practitioner can provide the query 115 by speaking a question or typing a question into the client device 130. The client device 130 can receive the query 115 from the client device 130, and provide the query 115 to the computing system 105. The query 115 can be or include a question or a query about the medical procedure video 117. The query 115 can be a question about the medical procedure video 117.

The queries 115 can be a post-procedure question or request for a prediction. For example, after the medical robotic system 110 performs a medical procedure, a medical practitioner can review the video 117, and ask questions about the recorded video 117. The computing system 105 can implement the generative model 165 after the medical procedure is implemented. The computing system 105 can execute the generative model 165 to answer hypothetical questions asked by a medical practitioner regarding the medical procedure, and predict surgical errors, medical emergencies, or other events that might occur during the medical procedure. For example, the computing system 105 can execute a bot, script, or other agent configured to generative hypothetical questions.

For example, the query 115 can be a question about an event that has occurred or will occur in the medical procedure video 117. For example, the event could be a collision, e.g., a collision between a tool, a robotic instrument, a robotic arm, or a robotic appendage and a body of the patient. The event can be a collision between robotic arms or between instruments. The query 115 can be a question about a medical practice, procedure, or technique that was used (or that could have been used) in the medical procedure video 117. For example, the query 115 can ask a question regarding what types of surgical errors are likely to occur during the medical procedure of the video 117. The computing system 105 can cause the generative model 165 to execute to generate a response 170 that indicates the types of surgical emergencies that are likely to occur during the medical procedure.

The video 117 can be a real-time stream from the medical robotic system 110. The computing system 105 can receive a stream or feed of the medical procedure video 117 as the procedure is performed. A medical practitioner, via the client device 130, can ask questions or provide queries 115 in real-time as the medical robotic system 110 performs a medical procedure, and the medical practitioner can receive real-time feedback or responses 170 as the medical robotic system 110 performs the medical procedure. The questions or queries 115 can be questions on how to resolve medical issues, what step or phase should be performed next to achieve a goal, etc. and the generative model 165 can be executed to produce responses 170 including answers or recommendations.

The query 115 can be or include text-based data. For example, the query 115 can be or include text asking a question in a natural language, e.g., English, Spanish, French, etc. The query 115 can included unstructured text data describing the question. For example, the unstructured text data can relate to a question about an event occurring or that might occur in the medical procedure video 117. The query 115 can be audio data. For example, the query 115 can include audio of a medical practitioner speaking the question. The query 115 can be image data, e.g., hand drawn annotations, a focused section or selection of a portion of a frame of the medical procedure video 117.

The GUI manager 120 can receive the query 115 from the client device 130 via the GUI 125. The GUI manger 120 can provide the query 115 to at least one prompt constructor 135. The computing system 105 can include at least one prompt constructor 135. The prompt constructor 135 can retrieve information based on or using the query 115. For example, the prompt constructor 135 can retrieve, using the query 115 information from the data repository 140. For example, the prompt constructor 135 can retrieve, using the query 115 at least a portion of medical resources 145, medical procedure videos 150, or kinematics data 155.

The data repository 140 can be a knowledgebase, a vector database, or another machine learning based database that stores data as features or embeddings. The data repository 140 can store single-mode data (e.g., only text, only video, only kinematics information, etc.) or multi-modal data (e.g., medical procedure videos 150, kinematics data 155, medical resource 145, data logged from the medical robotic system 110 that performed the particular medical procedure the query 115 is generated for, etc.). The data repository 140 can store features, feature vectors, or embeddings of the single model or multi-model data. For example, the data repository 140 can store embedding vectors of medical procedure videos 150. The prompt constructor 135 can generate an embedding vector of the query 115 or at least a portion of the medical procedure video 117, and use the embeddings to retrieve information from the data repository 140. For example, the prompt constructor 135 can use similarity metrics between embeddings of the query 115 or embeddings of the medical procedure video 117 to retrieve the pertinent or the most pertinent information from the data repository 140. The similarity metrics can be cosine similarity, Euclidean distance, hamming distance, a Jaccard index, etc. The data repository 140 or the prompt constructor 135 can implement at least one approximate nearest neighbor search and at least one similarity metric to identify relevant information to retrieve from the data repository 140.

The data repository 140 can be implemented on secured hardware or can be encrypted to prevent private information from being accessed by an unauthorized system. In some instances, an application including a pre-built reference data repository 140 can be implemented on an air-gapped computing system that includes identifiable information without privacy risk.

The prompt constructor 135 can retrieve at least one, or a portion of, medical resource 145 from the data repository 140. The medical resources 145 can be on, about, or describe medical procedures. The medical resources 145 can be medical literature, medical research papers, medical white papers, documented clinical studies, research on clinical studies, etc. The medical resources 145 can describe medical procedures, describe the steps or actions to perform medical procedures, describe the steps or actions to respond to emergencies (e.g., excess bleeding, bruising, burning), describe the steps or actions to avoid or prevent emergencies or unnecessary tissue damage, etc.

The prompt constructor 135 can retrieve at least one, or a portion of, medical procedure videos 150. The medical procedure videos 150 can be a historical collection of medical procedure videos recorded by the medical robotic system 110 (or other medical robotic systems 110 different than the medical robotic system 110 that produced the medical procedure video 117 that the medical practitioner is asking a question about). The medical procedure videos 150 can include a recorded audio track where a doctor, nurse, or other medical practitioner narrates the procedure, discusses the procedure, or makes comments or statements during the procedure, the computing system 105 can implement audio to text translation, implement language translation (e.g., translate language to English), or other pre-processing steps. The prompt constructor 135 can retrieve portions of the medical procedure videos 150 that are pertinent to answering the query 115, or provide context for answering the query 115. For example, the prompt constructor 135 can query the data repository 140 to identify frames or portions of medical procedure videos 150 that have a high similarity to the medical procedure video 117.

The prompt constructor 135 can retrieve at least one, or a portion of, kinematics data 155. The kinematics data 155 can be or include information, data, data frames, or values collected by or from the medical robotic system 110 when performing the medical procedure. For example, at least one medical robotic system 110 can collect and store kinematics data 155 for a medical procedure, and then transmit the kinematics data 155 to the computing system 105. The kinematics data 155 can be or include force, torque, acceleration, or velocity data of joints, links, arms, appendages, or manipulators of the medical robotic system 110. The prompt constructor 135 can retrieve kinematics data 155 pertinent to the query 115. For example, if the user asks how much force to apply to an anatomical structure, or how to manipulate an instrument of the medical robotic system 110, the prompt constructor 135 can retrieve force data from the data repository 140.

The prompt constructor 135 can generate, build, construct, compile, or provide at least one prompt 160. The prompt constructor 135 can construct the prompt 160 based on the query 115, the video 117, and the resources 145. The prompt constructor 135 can provide, send, transmit, or input the prompt 160 to at least one generative model 165. The prompt constructor 135 can provide the prompt 160 to the generative model 165 to generate the response 170 to the query 115. The prompt 160 can include at least a portion of the query 115 and the data retrieved from the data repository 140 (e.g., the medical procedure videos 150, the kinematics data 155, or the medical resources 145). The prompt 160 can be a data message, a dataset, a collection of data components, data elements, a data packet, etc. The prompt 160 can include a natural language request, e.g., include the query 115 or text of the query 115. The prompt 160 can be a multi-modal prompt, e.g., a prompt that includes text of the query 115, the medical procedure video 117, medical procedure videos 150 retrieved from the data repository 140, kinematics data 155 retrieved from the data repository 140, medical resources 145 retrieved from the data repository 140, etc. The multi-modal prompt 160 can include text in a natural language, video, images, kinematics information, data values, datasets, etc.

The prompt 160 can include the medical procedure video 117. The prompt 160 can include the entire medical procedure video 117. The prompt 160 can include a portion of the entire medical procedure video 117. The prompt 160 can include a portion of the medical procedure video 117 that the medical practitioner has already viewed. For example, the prompt constructor 135 can select the medical procedure video 117 from a starting time of the video (e.g., the beginning) to a current watch time (e.g., a time where the video was paused or a timestamp of the last frame or current frame to be displayed). For example, prompt constructor 135 can chunk the video 117 into parts, segments, or pieces, and include the relevant chunks of the video 117 in the prompt 160. The GUI manager 120 can track what portions or timestamps of the video 117 the user has viewed (e.g., if the user has moved forward or backward), and cause the prompt 160 to include chunks of the video 117 that correspond to the times of the video 117 that the user has viewed. In this regard, by tracking what portions of the video 117 the user has viewed, and including only the corresponding chunks (and not other chunks) the generative model 165 may not may any predictions that contradict events that have actually occurred in the video 117.

The prompt constructor 135 can cause a portion of the medical procedure video 117 to be included in the prompt 160, and prevent the generative model 165 from executing on an entirety of the video 117. For example, if a medical practitioner provides a query 115 that asks a question about what events are likely to occur at a future time during the medical procedure, the prompt constructor 135 can prevent the generative model 165 from executing on portions of the video 117 at the future time. If the generative model 165 executes on videos at the future time, the generative model 165 may respond with an indication of what event did occur, and not what types of events are likely to occur.

The prompt constructor 135 can determine a time or timestamp when the query 115 was generated, e.g., when the query 115 was provided by the client device 130 or when the medical practitioner provided the query 115 on the client device 130. The prompt constructor 135 can map or link the timestamp of when the query 115 was generated to a timestamp of the video 117. For example, the prompt constructor 135 can determine which timestamp of the video corresponds to the time when the query 115 was asked by the medical procedure. The prompt constructor 135 can construct the prompt 160 to prevent the generative model 165 from accessing frames of the video subsequent to the mapped timestamp of the video 117. For example, the prompt constructor 135 can generate or select a video clip from the video 117. The prompt constructor 135 can generate a video clip that includes frames of the video 117 with timestamps that are less than or equal to the mapped timestamp. In this regard, the video clip 117 can exclude or may not include any frames (or a few number of frames) of the video 117 that occur after the mapped timestamp of the video 117. The prompt constructor 135 can construct the prompt 160 to include or be based on the video clip.

Because the prompt constructor 135 can include a clip of the video 117 in the prompt 160, instead of the entire video 117, the size of the prompt 160 can be smaller than if the prompt 160 included the entire video 117. Furthermore, the number of tokens needed for the generative model 165 can be reduced since the prompt 160 is smaller. This can result in a lower amount of memory resources, processing resources, and power resources to execute the generative model 165 using the reduced size prompt 160.

The computing system 105 can execute the generative model 165 to generate, compose, output, or provide at least one response 170 using at least one prompt 160. The generative model 165 can execute using the prompt 160 as an input to the generative model 165. The generative model 165 can execute using the video 117 or the context retrieved by the prompt constructor 135, e.g., the kinematics data 155, the medical procedure videos 150, or the medical resources 145. The computing system 105 can include at least one generative model 165. The generative model 165 can be or include a LLM, a SLM, a world model, a ChatGPT model, a Claude model, a BERT model, a Llama model, a Gemini model, etc. A LLM can include a number of parameters that is on the order of trillions, e.g., 1-1.5 trillion parameters, 1.5-2 trillion parameters, more than 2 trillion parameters, etc. an SLM can include a number of parameters that is on the order of billions, e.g., 1-10 billion model parameters, 10-500 billion model parameters, 500 billion model parameters or more. Furthermore, the LLM can be generic, or may not be domain specific. An SLM can be domain specific, e.g., specific to the healthcare domain, specific to the surgical domain, etc. An LLM can be, for example, Claude, Gemini, ChatGPT, BERT, etc. An SLM can be, for example, DistilBERT, Orca 2, GPT-Neo, etc. A world model can be a model that learns or trains in a simulated environment.

The generative model 165 can be a pre-trained model, one already trained on a corpus of information, e.g., text data, image data, video data, kinematics data, multi-modal data, mathematical data, language based data, etc. By using a generative AI model 165, the computing system 105 can leverage both human-interpretable media and structured information, removing the need to manually generate rule-based chains for encoding knowledge across a variety of media. The generative model 165 can provide a conversational interface in the GUI 125 to the reference data repository 140 through the GUI 125

While the generative model 165 can be pre-trained, the generative model 165 can be augmented to executed on relevant data pertinent to answering medical queries 115. The computing system 105 can include at least one augmentation pipeline 175. The augmentation pipeline 175 can provide oversight in the quality of reference documents, and leverage several technologies and pretrained models to handle problems such as speech to text, optical character recognition, machine learning based computer vision technique, action recognition, and procedure and part-of-procedure labeling. The augmentation pipeline 175 can receive data from at least one data source 180. The data source 180 can be a repository, database, or collection of information. For example, the data source 180 can be one or multiple other medical robotic systems 110 that provide medical procedure videos 150, kinematics data 155, data that the medical robotic system 110 logged or saved. The data source 180 can be or include one or more cloud platforms, servers, computers, databases, etc. that the medical robotic systems 110 provide data to. The data source 180 can be a physician database or medical white paper database that stores and provides medical literature, medical research papers, medical white papers, medical research papers, documented clinical studies, research on clinical studies, etc. The augmentation pipeline 175 can execute offline separate from the execution of the generative model 165 to aggregate, chunk, and/or embed information in the data repository 140. In this regard, the generative model 165 may not need to wait for the augmentation pipeline 175 to execute before producing a response 170.

The augmentation pipeline 175 can include at least one chunking component 185. The chunking component 185 can receive data from the data source 180, and chunk the received data into chunks, parts, pieces, sections, or segments. The chunks of data can be smaller than the entire data set being chunked. The chunking component 185 can chunk medical resources 145 to produce chunks of a selected or set size. The size of the chunks that the chunking component 185 produces can be based on type of data, e.g., medical procedure videos 150 can have a first chunk size, kinematics data 155 can have a second chunk size, or medical resources 145 have a third chunk size. Furthermore, the chunk size can be set on the type of medical procedure that the medical resources 145 describes or relates to or that the medical procedure videos 150 or kinematics data 155 were recorded for. A first medical procedure can have a larger chunk size than a second medical procedure.

The chunking component 185 can provide the chunked data to at least one embedding component 190. The at least one embedding component 190 can generate an embedding, feature set, feature vector, etc. for the data received from the data source 180. The embedding component 190 can store the embeddings in the data repository 140. The embedding component 190 can embed the chunked data received from the chunking component 185. The embedding component 190 can be or include a model, such as an embedding model, to generate the embeddings from the data received from the chunking component 185 or data source 180. The embedding model can be a text based embedding model, a value based embedding model, or a video based embedding model.

For example, the embedding model can be an image based encoding model, such as an encoder-decoder based model, self-distillation with no labels (DINO) or masked Siamese network (MSN), auto encoders (AE), transformers, masked auto-encoders (MAEs), etc. The embedding model can be a text based embedding technique or model, such as Word2vec, a recurrent neural network, a long short-term neural network, a transformer, etc. The embedding component 190 can execute at least one embedding model using the received data, and store the embedded data in the data repository 140.

The augmentation pipeline 175 can augment the data repository 140 using the chunked and embedded data generated by the chunking component 185 and the embedding component 190. The augmentation pipeline 175 can augment the data repository 140 by storing the chunked and embedded information in the data repository 140. The augmentation pipeline 175 can augment the data repository 140 using data received from the data source 180. The augmentation pipeline 175 can produce a multi-media dataset and appropriate metadata that is aggregated, encoded, and stored in the data repository 140 to allow the generative model 165 to provide salient references when generating content. Different copies of the reference data repository 140 can be maintained to enable versioning and specializations. The data repositories 140 can be generated offline, separate from systems that are running the generative model 165.

The generative model 165 can generate, output, produce, provide, or synthesize the response 170. The response 170 can include at least one citation. The citation can be a reference to at least one of the medical resources 145. The citation can be or include a name or title of the medical resource 145, a name of an author of the medical resource 145, a publication date of the medical resource 145, an International Standard Book Number (ISBN), etc. The citation can include a page number, a column number, a line number, a paragraph number, a figure reference, a chart reference, etc. If the citation is to a video or audio recording, the citation can include a reference to a timestamp of the video or audio recording. The citation can include quotes or images from the medical resources 145. The citation can include a timestamp within the current video 117. The citation can cite or include spoken words of a surgeon narrating one of the medical procedure videos 150. The citation can include, be, or refer to a citation data structure that includes information about the citation, or a portion within the cited reference that is relevant to the response.

The generative model 165 can receive data for producing the citation from the prompt 160, for example, the prompt constructor 135 can include the name of the medical resource 145, the name of an author of the medical resource 145, the publication date of the medical resource 145, or the ISBN in the prompt 160. The generative model 165 can use text, charts, images, pictures, or other data of a particular medical resource 145 to generate text of the response 170, and then include a citation to the medical resource 145 that references the medical resource 145.

The prompt 160 can include a request that the generative model 165 produce a citation. For example, the request can be a text based request in a natural language, e.g., “Include a citation” or “Include a citation to a paper and/or another medical procedure.” The request can be a natural language request that specifies the format or information of the request, e.g., “Include a citation in the response that includes the name, author, and publication date of the reference.” The generative model 165 can be trained or constructed to output a citation in the response 170. For example, the generative model 165 may not need an input request that the generative model 165 output a citation, the generative model 165 can be set up to always, or normally, output a citation in the response 170. The response 170 can include multiple citations. For example, if the generative model 165 outputs a response 170 based on data of a first medical resource 145 and a second medical resource 145, the response 170 can include a first citation to the first medical resource 145, and a second citation to the second medical resource 145. The response 170 can be based on any number of medical resources 145, and can include multiple citations, one for each of the medical resources 145.

The generative model 165 can generate the response 170 to include multiple citations, each for a different fact or piece of information in the response 170. The generative model 165 can generate the response 170 to include multiple citations for the same fact or piece of information in the response 170. The generative model 165 can order citations in the response 170 according to weight or authority, e.g., greater authority citations before lower authority citations.

The computing system 105 can include at least one guardrail component 177. The guardrail component 177 can implement at least one guardrail as part of the presentation of generated content available to the user to ensure that information is grounded in the reference data repository 140 to reduce the likelihood of hallucinated content from being presented to the medical practitioner, e.g., content that may appear correct, but is not based in reality. The guardrail component 177 can analyze the output of the generative model 165 to suppress or stop any response 170 without a citation or without a proper citation from being transmitted to, or displayed on, the client device 130. The guardrail component 177 can prevent hallucinated responses 170 from being delivered to the client device 130. The guardrail component 177 can detect whether a response 170 is a hallucinated response or not. The guardrail component 177 can analyze the response 170 and citation of the response 170 to determine whether the response 170 is a hallucinated response. For example, the guardrail component 177 can compare the citation against information of the medical resources 145 (or the videos 150 or kinematics data 155) to confirm that the citation is accurate. For example, the guardrail component 177 can compare the author name, publication date, or ISBN number of the citation of the response 170 against the author names, publication dates, or ISBN numbers of the medical resources 145 to verify that the information of the citation is correct. Responsive to detecting or determining that the response 170 is hallucinated, or includes information that is inaccurate or not correct, the guardrail component 177 can suppress the response 170, or prevent the response 170 from being delivered to the client device 130. Furthermore, the guardrail component 177 can check or verify that each response 170 includes a citation. If the guardrail component 177 detects a response 170 that does not have a citation, the guardrail component 177 can suppress or prevent the response 170 from being delivered, transmitted, or display on the client device 130.

The guardrail component 177 can include or be a generative model. For example, the generative model of the guardrail component 177 can be a second generative model or a model different than the generative model 165. The second generative model of the guardrail component 177 can be or include a LLM, an SLM, a world model, a ChatGPT model, a Llama model, a Gemini model, a Claude model, a BERT model etc. The generative model of the guardrail component 177 can implement a guardrail. The guardrail can prevent hallucinated or low reliability responses 170 from being delivered to the client device 130. The guardrail component 177 can input the response 170 to the second generative model to determine whether the response 170 satisfies the guardrail. If the response 170 satisfies the guardrail, the computing system 105 can transmit the response 170 to the client device 130. If the response 170 does not satisfy the guardrail, the computing system 105 can suppress the response 170 to prevent the response 170 from being delivered to the client device 130.

The guardrail component 177 can determine a quality level or confidence level for the response 170. The confidence level can be a numeric score that quantifies how likely the response 170 is a hallucinated response, how correct or incorrect the response 170 is, how reliable the response 170 is, etc. The guardrail component 177 can determine the confidence level based at least in part on the response 170 (e.g., the body or text of the response 170 itself) and the citation of the response 170. The guardrail component 177 can analyze the citation to determine the strength of the citation. The guardrail component 177 can verify the information of the citation (e.g., title, author name, ISBN) or determine the strength of the citation (e.g., determine how many papers cite to the paper of the citation, determine the number and strength of the author's other papers, the number of forward citations of the paper, the strength of other papers that forward cite the paper, etc.). The guardrail component 177 can compare the text, values, or information of the body of the response 170 against information of the medical resources 145, to verify that the concepts or information asserted in the response 170 are actually supported by the medical resources 145.

The guardrail component 177 can output a confidence level based at least in part on the citation. The guardrail component 177 can compare the confidence level to a threshold. Based on the comparison of the confidence level to the threshold, the guardrail component 177 can determine whether to suppress or not transmit the response 170 to the client device 130. The guardrail component 177 can compare the confidence level to the threshold, and if the confidence level is less than the threshold, determine that the response 170 should be suppressed. Responsive to determining that the response 170 should be suppressed, the guardrail component 177 can prevent the computing system 105 from delivering the response 170 to the client device 130. The guardrail component 177 can prevent the response 170 from being delivered by deleting the response 170, not sending the response 170 to the GUI manager 120 that delivers the responses 170 to the client device 130, setting a flag or indicator for the response 170 so that the GUI manager 120 can use the flag to determine not to deliver the response 170 to the client device 130, etc. If the confidence level is greater than the threshold, the guardrail component 177 can determine that the response 170 should be delivered to the client device 130, and cause or allow the computing system 105 to deliver the response 170 to the client device 130.

If the guardrail component 177 determines that the response 170 is hallucinated or otherwise should not be delivered to the client device 130, the guardrail component 177 can cause a message to be provided to the client device 130 that indicates that the query 115 could not be responded to. For example, the message can indicate that the response 170 could not be generated with a level of reliability or confidence that the response 170 can be delivered to the client device 130. Even if the guardrail component 177 determines that the response 170 is hallucinated, the guardrail component 177 can cause a warning message to be delivered along with the response 170 indicating that the response 170 is unreliable, or does not have a confidence level greater than a particular level. Furthermore, the guardrail component 177 can transmit the confidence level to the GUI manager 120 for display on the client device 130. The GUI manager 120 can display the confidence in the GUI 125. Regardless of whether the response 170 is suppressed or not, the GUI manager 120 can cause the GUI 125 to include the confidence level for the response 170.

The GUI manager 120 can transmit the response 170 to the client device 130. The GUI manager 120 can cause the client device 130 to display the response 170 within the GUI 125. The GUI manager 120 can display the response 170 in a chat based interface. For example, the GUI 125 can include a chat based interface, e.g., an interface for a medical practitioner to input the queries 115, and view the responses 170 to the queries 115.

The GUI manager 120 can include at least one bot service 195. The bot service 195 can generate artificial queries 115 that users may ask, and generate a timestamp when the question would be asked. The bot service 195 can cause responses 170 to be generated for the artificial queries 115, and displayed in the GUI 125 at or shortly after the video 117 being played in the GUI 125 reaches the timestamp of the query 115. The artificial queries 115, along with their responses 170, can be displayed within a video playback GUI 125 as the user views the video 117, e.g., once the play time of the video reaches the timestamps when the artificial queries 115 are asked and responded to.

The bot service 195 can use the generative model 165 to generate artificial questions or queries 115 that a person might ask when watching the medical procedure video 117. The bot service 195 can provide a user experience where multiple queries 115 are generated by the bot service 195 and answered by the generative model 165, without the user needed to ask questions themselves. For example, the GUI manager 120 can execute the generative model 165 using at least a portion of the medical procedure video 117 to generate an artificial query 115. The generative model 165 (or another generative model besides the model 165) can be trained based at least in part on a set of historical queries 115. The generative model 165 can execute to predict queries 115 that ask questions that medical practitioners are likely to ask at various times when asking the medical procedure video 117.

The bot service 195 can generate a timestamp when the artificial query 115 would be asked, and generate a response 170 to be displayed at or shortly after the timestamp. For example, the prompt constructor 135 can generate prompts 160 that include a timestamp of the video 117 to generate a question about. The bot service 195 can analyze the video 117, and determine timestamps of the video 117 for which to ask one or multiple questions at. The bot service 195 can detect timestamps by analyzing movement, detecting transections, detecting bleeding, detecting burning, detecting removal of an anatomical structure, etc. in the medical procedure video 117, and for each detected event or portion of the video 117, select a corresponding timestamp of the video 117 for which to generate a query 115 with. The bot service 195 can generate prompts 160 that include a request to generate a query 115 for a specified frame, segment of the video 117, or timestamp of the video 117 using the timestamps identified by the bot service 195. The result of the prompts 160 can be queries 115 output by the generative model 165.

Using the generated queries 115, the prompt constructor 135 can generate prompts 160 for answering the queries 115. For example, the prompt constructor 135 can retrieve information from the data repository 140 for answering the queries 115, e.g., medical procedure videos 150, kinematics data 155, medical resources 145, etc. The generative model 165 can execute using the prompts 160 to generate responses for the queries 115. For example, the computing system 105 can execute the generative models 165 on the queries 115, the video 117, or the portions of the medical resources 145 retrieved from the data repository 140. Each, or at least one, of the responses 170 produced by the generative model 165 can include a citation to at least one medical resource 145.

The GUI manager 120 can transmit the queries and the responses to the client device to display in a graphical user interface on the client device responsive to a play time of the video 117 reaching the timestamps of the artificial queries 115. As the video 117 is played in the GUI 125, the GUI manager 120 can transmit the artificially generated queries 115 and corresponding responses 170 to the client device 130. For example, the GUI manager 120 can compare a play time or timestamp indicating which frame the medical practitioner is viewing to timestamps associated with the queries 115 and responses 170. When the current time is equal to the timestamp of an artificial query 115 and corresponding response 170 (or within a threshold length of time before or after the timestamp of the artificial query 115), the GUI manager 120 can cause the GUI 125 to display the artificial query 115 and subsequently display the response 170 to the artificial query 115.

The client device 130 can be a AR/VR device, such as an AR/VR headset, AR/VR goggles, AR/VR glasses, smart glasses, AR/VR contact lenses, a smartphone, a tablet, a laptop, a surgeon console, etc. The GUI manager 120 can include at least one AR/VR service 197. In addition to two dimensional (2D) based display of queries 115 and responses 170, the AR/VR service 197 can implement solutions for an immersive high quality learning experience. The AR/VR service 197 can collect AR/VR data (e.g., data streams or user input from the AR/VR device 30) and input the AR/VR data into the generative model 165 to produce a response 170. The AR/VR service 197 can execute the generative model 165 based on a video feed of an AR/VR headset 130 and/or typed or spoken queries 115 of a user. The generative model 165 can provide suggestions, answers, or recommendations to efficiently set up an operating room, prepare a robotic apparatus for surgery, prepare a patient for surgery, etc. The output of the generative model 165 can be data to display on the AR/VR headset or device 130.

The AR/VR service 197 can receive AR/VR data from an AR/VR device 130, or provide AR/VR data to the AR/VR device 130. The service 197 can receive AR/VR data from the client device 130, e.g., user questions and images or videos captured by the client device 130 of what the user is looking at. For example, a medical practitioner may look at a medical procedure room, look at the medical robotic system 110, look at instruments that are or are being installed on the medical robotic system 110, and ask questions about what the medical practitioner is looking at. The GUI manager 120 can produce or generate the query 115 using the question asked by the medical practitioner, and the frames or video captured by the client device 130 at or within a length of time from when the medical practitioner asked the question.

In some implementations, the computing system 105 can be deployed as an extension for a web browser, internet browser, or other application run on the client device 130. The extension can run for any surgical or medical video 117 displayed or viewed on the browser or on the application. For example, the extension can retrieve or record the video viewed on the client device 130, transmit or stream the video 117 back to the computing system 105 for executing the generative model 165. The extension can further provide a conversational interface, text based chat window, or chat interface for entering queries 115, and viewing responses 170. In some implementations, the computing system 105 can implement a submission and approval model, where users could submit a video 117 from a source, and following a quality assurance process, the video 117 can be made available to users. The quality assurance process can ensure high quality output.

The computing system 105 can be implemented for case observation or other learning opportunities such as simulation or training labs. The computing system 105 can provide a GAI tool available within the medical robotic system 110 that clinicians can interact with while performing simulations that can help guide users on how to complete procedures or how to improve techniques. The computing system 105 can provide a GAI solution that can provide a benefit to a trainee in a similar way that a trainer is able to guide and give feedback to clinicians during training sessions. In addition to virtual case observations and answering user questions, the computing system 105 can allow a medical practitioner to see or hear questions asked by other observers.

The computing system 105 can receive ratings from medical practitioners that rate other medical practitioners questions. The computing system 105 can display queries 115 and responses 170 with ratings greater than a threshold or at least a number of ratings. The GUI 125 can include an input element allowing a user to select how many questions asked by other users should be viewed in the GUI 125 as the user watches the video 117, or what level of rating or number of ratings are necessary for the question to be displayed in the GUI 125. The computing system 105 can cause the historical queries 115 and responses 170 to be displayed in the GUI 125 according to the user input.

The computing system 105 can store historical queries 115, historical responses 170, historical videos 117 of medical procedures performed by a particular surgeon, historical kinematics data 155 performed by a particular surgeon, etc. The computing system 105 can integrate and track the kinematic data, the clinical video, and a profile of the surgeon over time. The generative model 165 can recognize patterns that connect the data sources, ultimately contextualizing patient variation and differences in behavior and actions as part of the development of a surgeon. In this regard, the responses 170 provided by the generative model can inform surgeons on what types of techniques they should improve or adopt to improve their patient outcomes.

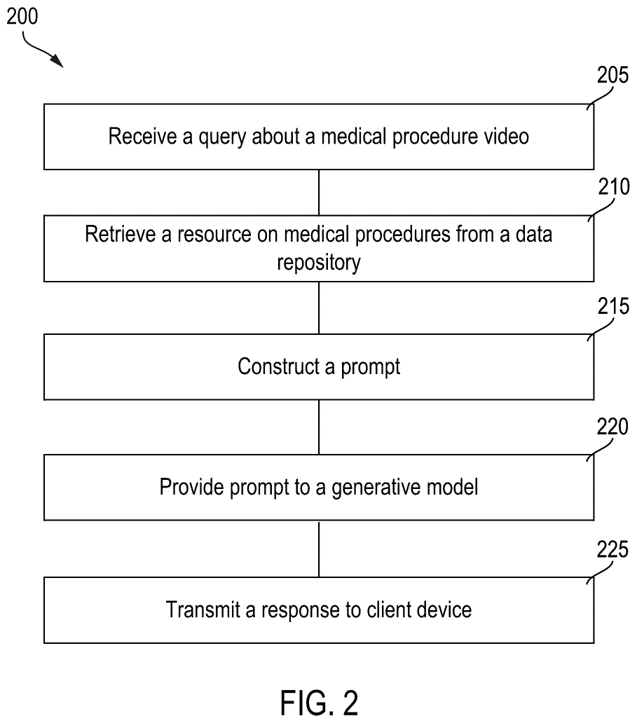

Referring now to FIG. 2, among others, an example method 200 of generating responses to medical procedure video queries using a generative model is shown. At least a portion of the method 200 can be performed by the computing system 105, the medical robotic system 110, the client device 130, or the data source 180. The method 200 can include an ACT 205 of receiving a query about a medical procedure video. The method 200 can include an ACT 210 of retrieving a resource on medical procedures from a data repository. The method 200 can include an ACT 215 of constructing a prompt. The method 200 can include an ACT 220 of providing a prompt to a generative model. The method 200 can include an ACT 225 of transmitting a response to a client device.

At ACT 205, the method 200 can include receiving, by the computing system 105, a query 115 about a medical procedure video 117. The computing system 105 can receive the query 115 in one or multiple formats, e.g., typed or written words, spoken words, annotations, or hand drawn images, etc. The computing system 105 can perform one or more operations to generate a query data structure 115 that is in a natural language. For example, the computing system 105 can generate text data from audio data or hand drawn data by executing one or more models trained by machine learning. For example, the computing system 105 can save the strings or text data into the query data structure 115. The query 115 can be a question about the video 117, e.g., about the medical procedure shown in the video 117. The question can be a question regarding how a portion of the medical procedure should be performed, the question can ask what types of events or emergencies are likely to occur during the medical procedure, the question can ask what types of actions should be avoided during the medical procedure, etc.

At ACT 210, the method 200 can include retrieving, by the computing system 105, a resource on medical procedures from a data repository. The computing system 105 can retrieve at least one or multiple medical resources 145 from the data repository 140. The computing system 105 can retrieve medical resources 145 that are pertinent or relevant to answering the question of the query 115. For example, the computing system 105 generate features or an embedding of the query 115, and compare the features or embedding against features or embeddings of the data repository 140. For example, the data repository 140 can be a vector database. The computing system 105 can use similarity metrics between embeddings of the query 115 or embeddings of the medical procedure video 117 to retrieve the pertinent or the most pertinent information from the data repository 140. The similarity metrics can be cosine similarity, Euclidean distance, hamming distance, a Jaccard index, etc. The computing system 105 can retrieve medical resources 145 for answering the query 115, but can also retrieve other procedure videos 150 or kinematics data 155 relevant to answering the query 115.

At ACT 215, the method 200 can include constructing, by the computing system 105, a prompt 160. The prompt 160 can be a data structure for the generative model 165 to generate an output with. The prompt 160 can be a data package that includes data of the query 115 and data retrieved from the data repository 140 (e.g., the medical procedure videos 150, the kinematics data 155, and the medical resources 145). The method can include creating one prompt 160 that combines the query 115 with the data retrieved from the data repository 140. The computing system 105 can generate a single or multi-modal prompt 160 used to generate one or multiple responses 170. For example, the prompt 160 can be only text, only video, only frames, only kinematics data, or a combination of text, videos, frames, and kinematics data.

At ACT 220, the method 200 can include providing, by the computing system 105, a prompt 160 to a generative model 165. The method 200 can include providing, by the computing system 105, the prompt 160 as an input that the generative model 165 executes on to produce an output response 170. The method 200 can include executing the generative model 165 with the prompt 160 as an input to output the response 170. The method 200 can include generating the response 170 to include at least one citation to the medical resources 145. The citation can be embedded within text of the response 170. The generative model 165 can be configured or trained to output citations in the response 170. The prompt 160 can include a statement or request that the generative model 165 generate the citation for the response 170, and the generative model 165 may not require any special configuration to produce the citation in the response 170.

At ACT 225, the method 200 can include transmitting, by the computing system 105, a response 170 to the client device 130. The method 200 can include causing the GUI 125 to display the response 170. The method 200 can include executing, by the computing system 105, a guardrail component 177 on the response 170 before the response 170 is delivered to the client device 130. The method 200 can include analyzing and verifying a citation in the response 170 to determine whether the citation is accurate and correct. The method 200 can include analyzing and verifying the response 170 to determine whether the body or text of the response 170 is accurate and correct. The method 200 can include detecting or determining whether the response 170 is hallucinated, e.g., a response 170 that asserts information that is false or is out of date. The method 200 can include suppressing or not transmitting the response 10 to the client device 130 if the response 170 is hallucinated.

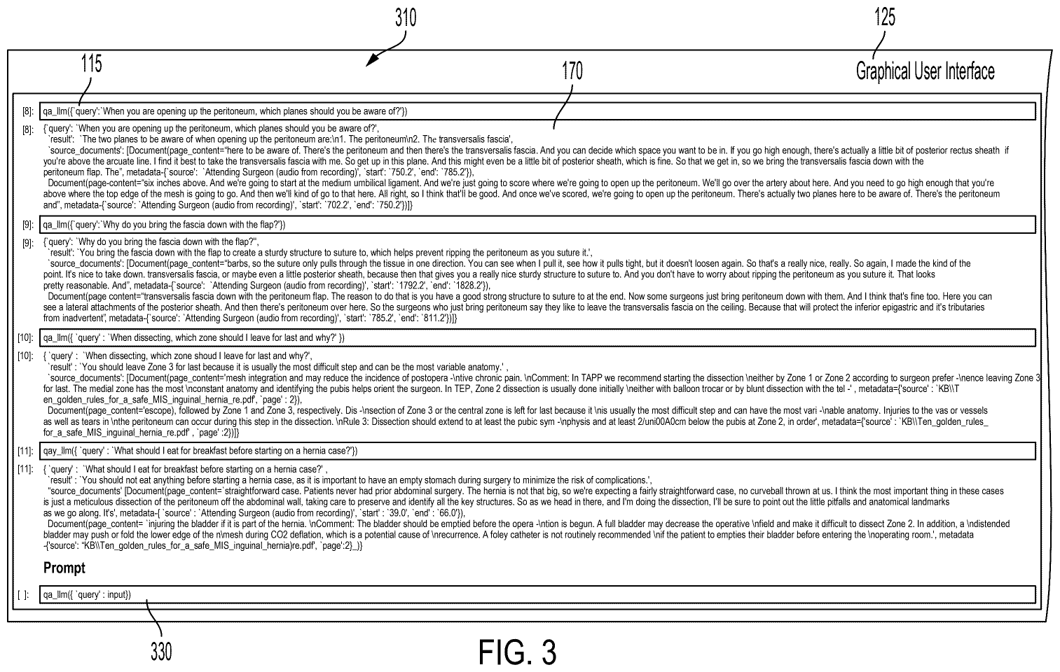

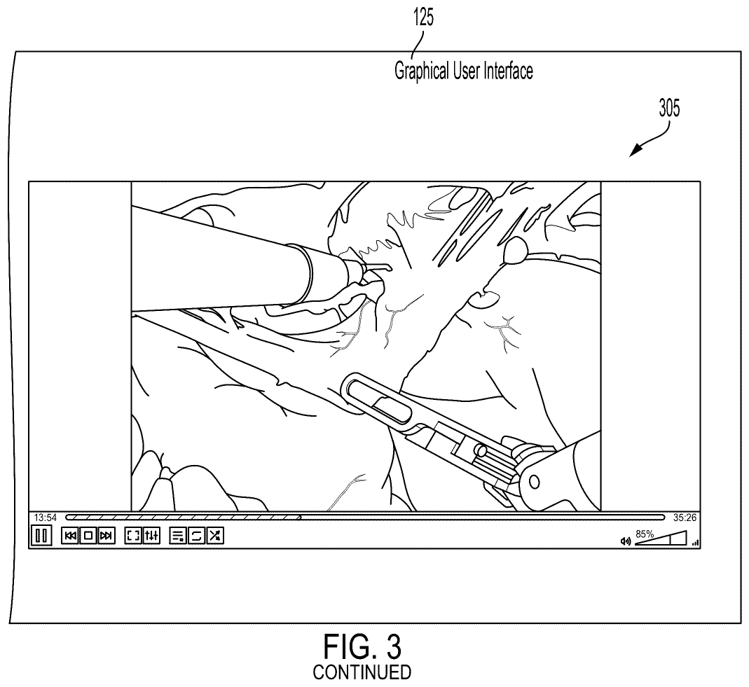

Referring now to FIG. 3, among others, an example GUI 125 including a video player 305 and an input 330 for a user to submit a query 115. The video player 305 can play the medical procedure video 117. The video player 305 can load and play the video 117 after the medical robotic system 110 captures the video and after the medical procedure is performed. The video player 305 can stream or play the video 117 in real-time as the medical robotic system 110 captures the video 117 and transmits the video 117 to the computing system 105.

The GUI 125 can include at least one chat interface 310. The chat interface 310 can be a window, a text interface, a chat-based text interface, a feed of queries 115 and responses 170, a multi-user chat interface, or multi-bot chat feed, etc. However, the interface 310 can be implemented through a variety of multi-modal interactions, e.g., audio based output, pictorial output, etc. The GUI 125 can include at least one input 330. The input 330 can be an editable text box or text interface that a user can type alphanumeric data into, e.g., numbers, letters, words, or phrases. The computing system 105 can receive the query 115 via the input 330. The chat interface 310 can include a list or history of queries 115 and the corresponding responses 170.

The GUI 125 can display the chat interface 310 and the video player 305 next to each other. For example, the GUI 125 can concurrently, simultaneously, or at the same time display the chat interface 310 and the video player 305. The GUI 125 can display the chat interface 310 and the video player 305 next to each other, so that the user can see both at the same time. The chat interface 310 can be displayed to the left of the video player 305, to the right of the video player 305, above the video player 305, or below the video player 305. The GUI 125 can display the chat interface 310 and the video player 305 one at a time, e.g., not at the same time, not concurrently, or not simultaneously. The frame displayed in the video player 305 can correspond to the frames used to generate the responses displayed in the chat interface 310.

In FIG. 3, one query 115 can be, “When you are opening the peritoneum, which planes should you be aware of?” The result 170 can be “The two planes to be aware of when opening up the peritoneum are: The peritoneum. The transversalis fascia.” The result 170 can include a citation to a source (e.g., an audio recording of another surgery by an attending surgeon) where the source content included in the citation is “here to be aware of. There's the peritoneum and then there's the transversalis fascia. And you can decide which space you want to be in. If you go high enough, there's actually a little bit of posterior rectus sheath if you're above the arcuate line. I find it best to take the transversalis fascia with me. So get up in this plane. And this might even be a little bit of posterior sheath, which is fine. So that we get in, so we bring the transversalis fascia down with the peritoneum flap. The citation can include a start time e.g., 750.2 and an end time e.g., 785.2 which can be timestamps or time indications of an audio or video recording. Furthermore, the result 170 can include a second citation to another source (or the same source) such as an audio recording of an attending surgeon. The citation can include source content from the source, such as “six inches above. And we're going to start at the medium umbilical ligament. And we're just going to score where we're going to open up the peritoneum. We'll go over the artery about here. And you need to go high enough that you're above here the top edge of the mesh is going to go. And then we'll kind of go to that here. All right, so I think that'll be good. And once we've scored, we're going to open up the peritoneum. There's actually two planes here to be aware of. There's the peritoneum and . . . ” The result 170 can include an indication of the source, e.g., an audio recording of an attending surgeon, and a start time, e.g., 702.2 and an end time, e.g., 750.2, of the audio recording used in the prompt 160 to generate the result 170.

The query 115 can be “Why do you bring the fascia down with the flap?” The result 170 can be “You bring the fascia down with the flap to create a sturdy structure to suture to, which helps prevent ripping the peritoneum as you suture it.” The result 170 can include at least one citation, e.g., a citation to an audio recording by an attending surgeon. The citation can include the source material used to produce the result 170, e.g., “barbs, so the suture only pulls through the tissue in one direction. You can see when I pull it, see how it pulls tight, but it doesn't loosen again. So that's a really nice, really. So again, I made the kind of the point. It's nice to take down, transversalis fascia, or maybe even a little posterior sheath, because then that gives you a really nice sturdy structure to suture to. And you don't have to worry about ripping the peritoneum as you suture it. That looks pretty reasonable.” The citation can indicate that the source content came from an attending surgeon audio recording, and indicate the start time, e.g., 1792.2, and end time, e.g., 1828.2, of the audio recording. The result 170 can include another citation, including source content, e.g., “transversalis fascia down with the peritoneum flap. The reason to do that is you have a good strong structure to suture to at the end. Now some surgeons just bring peritoneum down with them. And I think that's fine too. Here you can see a lateral attachments of the posterior sheath. And then here's peritoneum over here. So the surgeons who just bring peritoneum say they like to leave the transversalis fascia on the ceiling. Because that will protect the inferior epigastric and its tributaries from inadvertent.” The citation can include an indication of the source type, e.g., that the citation is of an audio recording of an attending surgeon, and a start time, e.g., 785.2, and an end time, e.g., 811.2, of the audio recording used in the prompt 160 to generate the response 170.

The query 115 can be “When dissecting, which zone should I leave for last and why?” The result 170 can be “You should leave Zone 3 for last because it is usually the most difficult step and can have the most variable anatomy.” The result 170 can include a citation to a document. The result 170 can include source content, e.g., “mesh integration and may reduce the incidence of postoperative chronic pain. In TAPP we recommend starting the dissection either by Zone 1 or Zone 2 according to surgeon preference leaving Zone 3 for last. The medial zone has the most inconsistent anatomy and identifying the pubis helps orient the surgeon. In TEP, Zone 2 dissection is usually done initially either with balloon trocar or by blunt dissection with the tel.” The citation can include a name of the source, “Ten_golden_rules_for_a_safe_MIS_ingeuinal_hernia_re.pdf” and a page number of the source content used in the prompt 160 to generate the response 170. The result 170 can include another citation to another source. The source content can include “followed by Zone 1 and Zone 3, respectively. Dissection of Zone 3 or the central zone is left for last because it is usually the most difficult step and can have the most variable anatomy. Injuries to the vas or vessels as well as tears in the peritoneum can occur during this step in the dissection. Dissection should extend to at least the pubic symphysis and at least below the pubis at Zone 2 in order.” The citation can include where the information was sourced from, including a reference, access date, page, quote, and an identifier for the specific resource on the system, e.g.: “Claus, Christiano, Marcelo Furtado, Flavio Malcher, Leandro Totti Cavazzola, and Edward Felix. “Ten golden rules for a safe MIS inguinal hernia repair using a new anatomical concept as a guide.” Surgical endoscopy 34 (2020): 1458-1464. https://doi.org/10.1007/s00464-020-07449-z Accessed Apr. 25, 2024. p1460: “The bladder should be emptied before the operation is begun. A full bladder may decrease the operative field and make it difficult to dissect Zone2.” In file: Ten_golden_rules_for_a_safe_MIS_inguinal_hernia_re.pdf”

The query 115 can be “What should I eat for breakfast before starting on a hernia case?” The result 170 can be “You should not eat anything before starting a hernia case, as it is important to have an empty stomach during surgery to minimize the risk of complications.” The result 170 can include a citation to a source, which can be an audio recording of an attending surgeon. Source content of the source can be included in the result 170, and can include “straightforward case. Patients never had prior abdominal surgery. The hernia is not that big, so we're expecting a fairly straightforward case, no curveball thrown at us. I think the most important thing in these is just a meticulous dissection of the peritoneum off the abdominal wall, taking care to preserve and identify all the key structures. So as we head in there, and I'm doing the dissection, I'll be sure to point out the little pitfalls and anatomical landmark as we go along.” The citation can include starting and ending times for the source content, e.g., 39.0 and 66.0. The result 170 can include another citation including source content, “injuries the bladder if it is part of the hernia. The bladder should be emptied before the operation is begun. A full bladder may decrease the operative field and make it difficult to dissect Zone 2. In addition, a distended bladder may push or fold the lower edge of the mesh during CO2 deflation, which is a potential cause of recurrence. A foley catheter is not routinely recommended if the patient to empties their bladder before entering the operating room.” The citation can include a name of the citation, e.g., “Ten_golden_rules_for_a_safe_MIS_inguinal_hernia_re.pdf” and a page number from which the source content was taken.

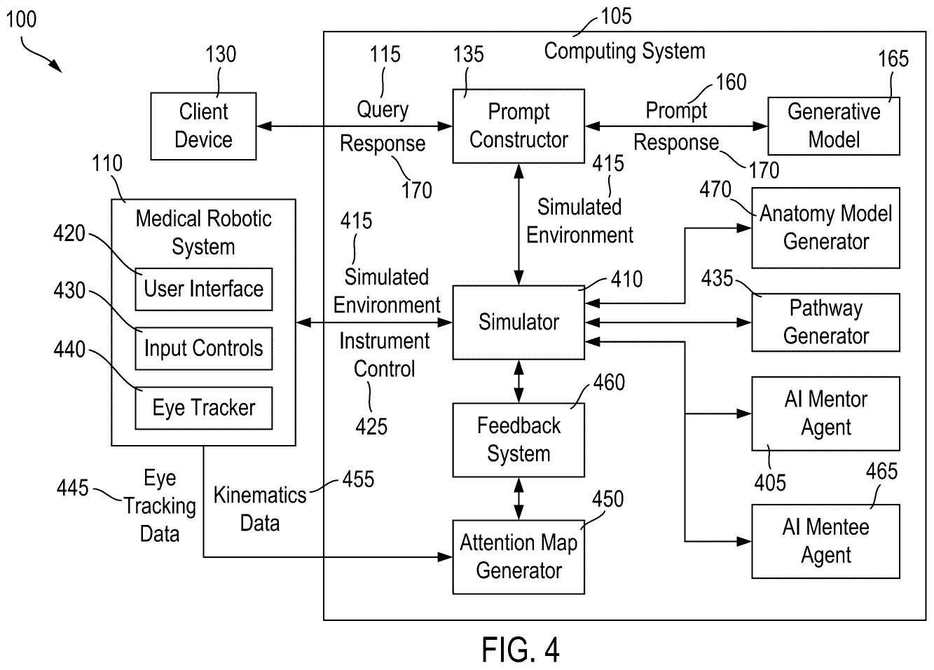

Referring now to FIG. 4, among others, an example computing system 105 to simulate a medical procedure is shown. The simulation can include an AI mentor 405. The computing system 105 can include at least one simulator 410. The simulator 410 can be or include at least one software component or hardware component. The simulator 410 can be or include an application, an executable, a machine learning model, a script, a set of instructions, etc. The simulator 410 can be a hardware component, such as a graphics processing unit (GPU), an application specific integrated circuit (ASIC), a system on a chip (SOC), or any other processing or logic circuit.

The simulator 410 can generate a simulated environment 415 for a simulated medical procedure and cause the medical robotic system 110 or the client device 130 to display a view of the simulated environment 415. The simulated environment 415 can be or include image data or video data to be displayed within a graphical user interface. The simulator 410 can generate or store various 3D objects or models (e.g., 3D models of patients, anatomical structures, or instruments). The simulator 410 can generate the simulated environment 415 to include a scene including multiple different 3D objects or models. The simulator 410 can simulate lighting in the simulated environment 415. The simulator 410 can simulate physics in the simulated environment 415. The simulator 410 can be or include an engine such as the UNREAL ENGINE, the UNITY ENGINE, CRYENGINE, etc. The simulator 410 can include a library of various object models, or can create custom or synthetic object models.

The simulator 410 can be or include at least one generative model to produce the simulated environment 415. The generative model can be a 3D generative AI model that outputs a three dimensional mesh, texture file, or other objects for the simulated environment 415. The generative model can transform an image into a 3D mesh or an object for the simulated environment 415. In some implementations, pre-surgical images received from imaging or mapping technologies can be used to produce data for executing the generative model on. The generative model can receive text or parameters, and output 3D information using the text or parameters. For example, the generative model can a model or technique (or a combination of techniques) such as Neural Radiance Fields (NeRF), Scene Representation Network (SRN), Local Light Field Fusion (LLFF), Stable Diffusion, Stable Diffusion XL (SDXL). The generative model can be a model that is part of a generative AI tool, such as MESHY, STABLE ZERO123, ALPHA3D, etc.

The simulator 410 can generate or animate 3D objects or models that can be or include general anatomical 3D models for use in building, maintaining, or animating the simulated environment 415. The 3D models 260 can be or include anatomical structures, instruments, bodily fluids (e.g., blood, interstitial fluid, saliva, gastric juice, etc.), peripheral objects (e.g., a surgical needle, an ultra-sound probe, etc.), etc. The 3D models 260 can model the physical attributes, shape, geometry, mesh, texture, size, or other information of the various elements.

The simulator 410 can provide the simulated environment 415 in an interactive and virtual manner on the client device 130 or the medical robotic system 110. For example, the simulator 410 can render the virtual environment 415 for display on a user interface 420. The simulated environment 415 can be rendered to include models of one or multiple anatomical structures of a patient, such as bones, organs, veins, arteries, muscles, tissue, etc. The simulated environment 415 can be a simulation of a virtual space (e.g., such as an operating room, medical procedure room, doctor's office, etc.). Furthermore, the simulated environment 415 can include objects or models of at least one medical instrument (e.g., a scalpel, a scissors, a monopolar curved scissors (MCS), a cautery hook tip, a cautery spatula tip, a needle driver, a forceps, a tooth retractor, a drill, or a clip applier), doctors or surgeons, an operating table, instrument table, operating light, a medical robotic system, etc. The simulator 410 can simulate an entire medical procedure or a portion of an entire surgical procedure. An operator of the medical robotic system 110 can select a medical procedure or a portion of a medical procedure to perform by providing input via the user interface 420 or the client device 130. The operator can choose to practice entire procedures or specific segments of a procedure (e.g., suturing). Practicing small portions of a medical procedure can allow for focused skill refinement. Furthermore, the simulator 410 can dynamically adjust parameters or attributes of the simulation based on user feedback and past performance of an operator.

The simulator 410 can simulate the physics of an anatomical structure. For example, the simulator 410 can simulate the anatomical structure depressing when pressed by a virtual instrument. The simulator 410 can simulate the anatomical structure being bent, twisted, or pushed/pulled by a virtual instrument in the simulated environment 415. The simulator 410 can simulate an anatomical structure bleeding, simulate an anatomical structure leaking fluid, bruising on the anatomical structure, etc.

The simulator 410 can simulate various types of medical procedures or surgical procedures. For example, the simulator 410 can simulate a polypectomy, a cataract surgery, a caesarean section, an appendectomy, or any other type of medical procedure, surgical procedure, or procedure. A user can provide input to the simulator 410 via the user interface 420 or the client device 130 to select a type of medical procedure for the simulator 410 to simulate, or a portion of a medical procedure for the simulator 410 to simulate (e.g., just an incision phase of a longer medical procedure or just a reconstruction phase of a longer medical procedure). Responsive the user selection, the simulator 410 can simulate the entire medical procedure or a portion of the medical procedure selected by the user.

The simulator 410 can receive instrument control 425 from the medical robotic system 110. The simulator 410 can receive the instrument control 425 from input controls 430 of the medical robotic system 110. For example, the input controls 430 can be buttons, switches, levers, joysticks, yokes, etc. The input controls 430 can be any input device, hand control, or foot control allowing a user to provide input to control, move, turn, rotate, or otherwise manipulate the various instruments or endoscopes rendered in the simulated environment 415. The computing system 105 (e.g., the simulator 410) can receive input from the medical robotic system 110 (e.g., the instrument control 425) to manipulate a simulated instrument in the simulated environment 415. The user interface 420 and the input controls 430 can be part of a virtual reality (VR) system or augmented reality (AR) system of the medical robotic system 110. For example, the VR or AR system can be a head-mounted display, e.g., VR/AR glasses, VR/AR goggles, VR/AR smart contact lenses, or a heads-up display. The user interface 420 can be a non-immersive display, for example, a tablet or monitor. As an example, the user interface 420 can be a laparoscopic training interface.

The simulator 410 can animate movement of the instrument within the simulated environment 415 based on the instrument control 425 received from the medical robotic system 110. Responsive to receiving the instrument control 425 from the medical robotic system 110, the simulator 410 can animate or render movement or motion of the various instruments or endoscopes in the simulated environment 415. If the view of the user in the simulated environment 415 is the viewpoint of an endoscope, a control input 425 moving the endoscope can move the viewpoint viewed by the user in the simulated environment 415. For example, based on the instrument control 425, the simulator 410 can animate the artificial instrument up, down, forward, backwards, left, right. For example, the instrument control 425 can include moving the instrument along x, y, and z axes (axes of a body of the instrument or axes of the simulated environment 415). Furthermore, the instrument control 425 can rotate the instrument about each of the x, y, and z axes.

The instrument control 425 can open or close a tip of the instrument. For example, if the instrument is a scissors, grasper, forceps, needle driver, etc. the instrument control 425 can open or close the tip of the instrument, or open or close the tip of the instrument to varying degrees. The instrument control 425 can activate or deactivate an electrical component of an instrument to burn or cauterize tissue. The instrument control 425 can activate a clip applier to apply a clip. The instrument control 425 can activate or deactivate a suction of a suction instrument.

The computing system 105 can include at least one pathway generator 435. The pathway generator 435 can be or include an application, an executable, a machine learning model, a script, a set of instructions, etc. The pathway generator 435 can generate a personalized training path or pathway for a medical practitioner that operates or controls the medical robotic system 110. The pathway generator 435 can analyze user data over time, the identify areas for improvement and customize a learning pathway such that the end user is positively encouraged to improve proficiency in a skill set over time. The pathway includes skill drills and practice scenarios designed to address weaknesses while building on strengths. The personalized training path can be a set or series of simulated tasks to be completed by an operator in a particular or predefined order. The training path can order the tasks in a sequence. Each task in the pathway can be a different simulated medical procedure to perform or a specific surgical step or action to practice. The tasks can be ordered in a series, and the tasks can build in difficulty or complexity. The pathway generator 435 can use or evaluate historical data, trends, and/or real-time feedback to create a unique learning pathway one medical practitioner or for each of a group of medical practitioners. The pathway generator 435 can receive or collect historical performance indicators of an operator of the medical robotic system. The performance indicators can be metrics identifying the quality or success of a medical procedure performed by the operator. The performance indicators can be collected or generated from real medical procedures performed by the operator with the medical robotic system 110. The performance indicators can be collected or generated from simulated medical procedures performed by the operator within a simulated environment 415 simulated by the simulator 410.

The pathway generator 435 can generate a learning pathway based on a comparative analysis of an operator with an expert surgeon. For example, the pathway generator 435 can receive comparative data comparing one or more metrics determined for an operator of the medical robotic system 110 with metrics of expert surgeons. Based on the comparison, the pathway generator 435 can build the learning pathway.

The pathways can allow an operator of the medical robotic system 110 to improve their skills in a way that reflects individual progress by training in their areas for development. For example, if historical performance indicators for an operator indicates that the operator causes high levels of bleeding during their medical procedures, the pathway generator 435 can generate one or multiple tasks that simulate the medical procedures that the operator caused high levels of bleeding in. Furthermore, the tasks can be scored or graded based on simulated levels of bleeding, to help a user identify bleeding levels and reduce bleeding levels. Similarly, if the historical performance indicators indicate that an operator has a high level of unsuccessful medical procedures of a particular type (e.g., appendectomy) the simulator 410 can generate a series of tasks practicing various steps of the particular type to assist the operator with learning and improving.

The pathway generator 435 can store various pathways for various operators. The pathway generator 435 can identify a task of the series of tasks of a pathway for a particular operator and cause the simulator 410 to initiate or begin simulating the task, e.g., generate a simulated environment 415. For example, each time a medical practitioner logs in or connects with the computing system 105 to perform a simulated medical procedure, the pathway generator 435 can generate data to be displayed on the user interface 420 recommending a user begin the next scheduled simulated task or simulated medical procedure. Responsive to a user selecting a task of the pathway or approving a recommended task of the pathway, the simulator 410 can generate an interactive simulation (e.g., a new simulated environment 415) for the operator of the medial robotic system 110 to complete.

The medical robotic system 110 can include at least one eye tracker 440. The eye tracker 440 can include at least one camera and at least one infrared or near-infrared light source to track movement or motion of at least one eye of an operator of the medical robotic system 110. The IR light generator can emit IR light towards the eye of the operator, which can be reflected off of the cornea and pupil of the eye of the operator. The camera can be sensitive to IR or near IR light, and generate a video feed of the eye of the patient based on the reflected light. Based on the video feed, the eye tracker 440 (or the computing system 105) can run one or multiple algorithms or machine learning techniques to detect movement of an eye of the operator, motion of an eye of the operator, or points on the user interface 420 that the operator has looked at. If the operator of the medical robotic system 110 looks at the user interface 420 to view a video feed of an endoscope of the medical robotic system 110, the eye tracker 440 can determine which portions of the user interface 420 that the operator looks at by tracking motion or movement of the eyes of the operator.

The eye tracker 440 can output eye tracking data 445. The eye tracking data 445 can include the video feed of the eye tracker 440 and/or the video feed of the user interface 420. The eye tracking data 445 can indicate or include the motions or movements of the eye of the operator of the medical robotic system 110. In some embodiments, the eye tracking data 445 is a trace of the focus point of an eye of the operator in a two dimensional window corresponding to a display of the user interface 420. For example, the eye tracking data 445 can be a series of coordinates on the user interface 420 that the operator looked at over time. The eye tracking data 445 can be captured by the eye tracker 440 for medical procedures performed by various operators of the actual live medical procedures. The eye tracking data 445 can be captured by the eye tracker 440 for simulated medical procedures performed by various operators of the medical robotic system 110.

The computing system 105 can include at least one attention map generator 450. The attention map generator 450 can be or include an application, an executable, a machine learning model, a script, a set of instructions, etc. The attention map generator 450 can receive, retrieve, collect, or store eye tracking data 445 or kinematics data 455 from at least one or multiple expert or top-performing operators or surgeons for various medical procedures (e.g., real medical procedures or simulated medical procedures). The attention map generator 450 can generate various heatmaps or attention maps using the eye tracking data 445 or the kinematics data 455. For example, the attention map generator 450 can generate a first attention map for eye tracking data 445, a second attention map for a first instrument positions indicated by the kinematics data 455, a third attention map for second instrument positions indicated by the kinematics data 455, etc. The attention map generator 450 can cause the user interface 420 or the client device 130 to display the attention maps or heatmaps to allow trainees to visualize where expert surgeons focus (e.g., look with their eyes) or move their instruments during critical moments of a procedure, such as suturing or dissection. In some embodiments, the attention map generator 450 can overlay real-time kinematic data 455 and/or real-time eye tracking data 445 from a trainee onto the various expert attention maps, offering feedback on where improvements could be made to better match expert techniques.

The attention map generator 450 can generate an attention map using the eye tracking data 445. The attention map generator 450 can produce, generate, create, or update an attention map for an operator using the eye tracking data 445. The attention map can indicate, for a particular medical procedure, what the points of attention of the operator were. The attention map can be a data structure, such as a heat map, that indicates how frequently an operator looked at various points on the user interface 420. The heatmap can include multiple points or sections, and a corresponding level or value for each point or section. Each level can indicate a length or duration of time that the operator of the medical robotic system 110 looked at the corresponding point. For example, the attention map can be a two-dimensional data structure including various points or sections (e.g., squares) making up a two dimensional structure corresponding to the user interface 420. The attention map generator 450 can generate a data value indicating a length of time that the operator looked at each section. For example, the attention map generator 450 can generate a data value indicating the proportion of time that the operator looked at each section of the data structure relative to the length of the entire medical procedure.

In some embodiments, the attention map generator 450 generates a 3D attention map. The attention map generator 450 can generate an attention map relative to the anatomical structure or the patient that the operator is performing the medical procedure on, instead of relative to the user interface 420. For example, the attention map generator 450 can generate a 3D representation of the patient and/or the anatomical structures of the patient, and can identify, based on the eye tracking data 445, what points in the 3D representation that the operator looked at. The attention map generator 450 can generate a 3D map formed by various 3D sections, e.g., boxes or prismatic shapes. The attention map generator 450 can generate a value for each 3D section of the 3D map indicating the length of time (e.g., length of time proportional to the length of time of the entire procedure).

The attention map generator 450 can cause the user interface 420 or the client device 130 to display the attention map generated by the attention map generator 450. For example, the attention map generated by the attention map generator 450 for a particular medical procedure (or simulated medical procedure) can be generated for one or multiple expert surgeons. The attention map generator 450 can be viewed by an operator or a trainee so that the trainee can understand what expert surgeons are looking at or looking for when conducting a medical procedure. For example, one or multiple expert surgeons can perform a particular simulated medical procedure, and the attention map generator 450 can generate one or a series of attention maps for the various expert surgeons. The attention map generator 450 can generate a single averaged attention map, or can generate a series of averaged attention maps, for example, one attention map for each of multiple segments of time that the entire simulated medical procedure is broken into. As a trainee performs the same simulated medical procedure, the attention map generator 450 can receive eye tracking data 445 from the medical robotic system 110. The attention map generator 450 can cause the displayed attention map for expert surgeons to be overlaid with the real-time trace or track of the eye motions of the trainee. In this regard, the trainee can receive real-time feedback of how their eye attention corresponds (or does not correspond) with the eye attention of expert surgeons.

The medical robotic system 110 can collect and send kinematics data 455 to the attention map generator 450. The kinematics data 455 can indicate the movements, motions, locations, or orientations of the various instruments or endoscopes of the medical robotic system 110. The kinematics data 455 can be tracked and collected over time as the operator of the medical robotic system 110 performs a medical procedure or simulated medical procedure. The attention map generator 450 can generate an attention map or heat map that represents the positions or motions of the instruments or endoscopes of the medical robotic system 110 during the medical procedure. For example, the attention map generator 450 can generate an attention map for each individual instrument or endoscope indicating the locations or positions of the instrument during the medical procedure.

The computing system 105 can include at least one feedback system 460. The feedback system 460 can generate feedback data to be displayed to an operator (e.g., a trainee) of the medical robotic system 110. The feedback system 460 can be or include an application, an executable, a machine learning model, a script, a set of instructions, etc. The feedback system 460 can generate feedback data, such as metrics, recommendations, comparisons between expert data and trainee data, etc. The feedback system 460 can perform a comparative performance data analysis to enable clinicians to understand how they are performing in relation to key opinion leaders, expert surgeons, and/or peers. This can foster continual growth and benchmarking against top performers or peers. The feedback system 460 can compare performance data of a trainee or clinician with a field leader or expert to allow the trainee to view how their techniques align or differ with the field leaders or experts. For example, the feedback system 460 can compare eye tracking data 445 of a trainee against eye tracking data 445 of an expert. The feedback system 460 can compare kinematics data 455 of a trainee against the kinematics data 455 of an expert. For example, after a trainee completes a simulated medical procedure (or a portion of the simulated medical procedure) the attention map generator 450 can generate an attention map for the operator. The feedback system 460 can cause the user interface 420 or the client device 130 to display the trainee's attention map side by side with an expert's attention map. The attention map generator 450 can display the trainee's attention map overlaid on top of the expert's attention map, or vice versa. Similarly, the feedback system 460 can receive kinematics attention maps for expert surgeons from the attention map generator 450, and display a kinematics attention maps with overlaid real-time kinematics data 455 of a trainee. Similarly, the feedback system 460 can display an expert's kinematics attention map along with a trainee's kinematics attention map to allow a trainee to compare their performance with an expert's performance.

The feedback system 460 can track improvement or degradation of a trainee's performance in the simulated environment 415. For example, the feedback system 460 can track one or multiple metrics over time, and build trends of the metrics for a trainee. For example, the feedback system 460 can determine objective performance indicators (OPIs) and track the OPIs. The OPIs can quantify an operators performance performed by an operator of the medical robotic system 110 in the simulated environment 415. The feedback system 460 can receive data from the simulator 410 or another data repository indicating the movements, motions, or rotations of the various instruments or endoscopes of the medical robotic system 110. For example, the data can be the instrument control decisions 425 of the operator of the medical robotic system 110. The feedbacks system 460 can receive simulated energy consumption levels, simulations of operations of a clutch or brake of the medical robotic, etc. The feedback system 460 can generate OPIs using the collected data. The OPIs can include different metric type. For example, one OPI can indicate an amount of energy or power consumed by the robotic medical system 110. The OPIs can include an indicator for total duration of a segment of the medical procedure. The various OPIs can include an OPI indicating a total linear distance traveled by an instrument of the robotic medical system 110 during a segment. The OPIs can include an OPI indicating a total angular distance of the instrument of the robotic medical system 110 during the segment. The OPIs can include an OPI indicating a total number of operations or a clutch or brake of the medical robotic system 110.

In some embodiments, the feedback system 460 can collect and determine OPIs for various expert surgeons. For example, the feedback system 460 can determine average OPIs for expert surgeons performing a particular simulated medical procedure or a real medical procedure. When a trainee performs the same simulated medical procedure, the feedback system 460 can generate OPIs for the trainee, and compare the trainee's OPIs with the expert surgeon's OPIs. For example, the feedback system 460 can generate graphic data for the user interface 420 or the user device 130 to display. The graphic data can be comparisons between the trainee's OPIs and the expert surgeon's OPIs. For example, the graphic data can be side-by side comparisons of the OPIs of the trainee and the OPIs of the expert surgeons. The graphic data can be a trend or plot of the OPIs of the trainee overlaid with OPIs of the expert surgeon over time through the simulated medical procedure. This can allow a trainee to identify what portions of the simulated medical procedure that the expert surgeon used more or less energy, operated the clutch more or less, etc. and compare their own performance with that of the expert surgeon.

The feedback system 460 can provide real-time skill tracking and feedback. For example, the feedback system 460 can continuously track a clinician's performance, and identify key areas for improvement and feed the identified areas for improvement into future training sessions. The feedback system 460 can determine or receive performance results of various simulated medical procedures performed by an operator in the simulated environment 415. The performance results can be received for different types of medical procedures, different segments of a medical procedure, different actions of a medical procedure, etc. For example, the performance results can be different OPIs or metrics quantifying the performance of the operator to perform different complete simulated medical procedures or different portions of the simulated medical procedure.

The feedback system 460 can analyze the performance results to determine performance issues. For example, the feedback system 460 can use the performance results to determine one or multiple areas that an operator needs to improve. For example, the performance issue can indicate that the operator has difficulty successfully making incisions, or the operator has difficulty in stitching a particular organ after performing a procedure. Similarly, the performance issue can indicate that the operator has trouble performing a particular medical procedure, e.g., performing an appendectomy. The feedback system 460 can detect that the operator has a performance issue by comparing the operator's performance metrics to an expert's performance metrics (or performance metrics averaged for multiple experts). Responsive to a deviation between the operator's performance metrics and the expert's performance metrics being greater than a particular amount, the feedback system 460 can detect the performance issue. For example, the feedback system 460 can compare one or multiple performance metrics of an operator against one or multiple performance metrics of corresponding categories of an expert. If the deviation of one performance metric type, or an aggregate deviation of multiple metric types is greater than a threshold, the feedback system 460 can detect the performance issue.

The feedback system 460 can generate or construct a surgical environment or a 3D anatomical structure based on the performance issue. For example, the feedback system 460 can generate the simulated environment 415 to focus on or practice the surgical procedure or portions of the surgical procedure that the operator needs to practice. For example, the feedback system 460 can communicate areas of improvement or performance issues to the pathway generator 435, and the pathway generator 435 can generate or adapt various tasks in a training pathway for an operator. This can lead to continuous improvement and skill mastery for operations of the medical robotic system 110.

The computing system 105 can include at least one AI mentor agent 405. The AI mentor agent 405 can be or include an application, an executable, a script, a set of instructions, etc. The agent 405 can be an intelligent agent (IA) that can perceive an environment (e.g., the simulated environment 415) and take actions in the simulated environment 415 (e.g., perform surgery with the simulated instruments in the simulated environment 415). For example, the AI mentor agent 405 can simulate expert surgeon techniques and attention points based on real-world data (e.g., eye tracking data 445, kinematic data 455, etc. recorded for sessions performed by expert surgeons). The computing system 105 can generate the AI mentor agent 405 based on data from key opinion leaders or expert surgeons. An operator can practice in the simulated environment 415 along with a virtual representation of an expert surgeon provided via the AI mentor agent 405.

For example, the AI mentor agent 405 can receive, read, or sense the simulated environment 415 by reading or retrieving information of the simulated environment 415, such as data indicating the position of simulated instruments in the simulated environment 415, the position of the simulated anatomical structures of the patient in the simulated environment 415, the status or state of the anatomical structures, etc. For example, the AI mentor agent 405 can receive data describing the 3D anatomical structures in the simulated environment 415. Based on the received data of the simulated environment 415 (e.g., the 3D model of the anatomical structure) at least one model of the AI mentor agent 405 can be executed to determine at least one action to perform. For example, the AI mentor agent 405 can generate commands to control or move the instruments or endoscopes in the simulated environment 415. For example, the AI mentor agent 405 can write command data or send command data to the simulator 410 to cause the simulator 410 to animate the movements, motions, or rotations of the simulated instruments.

The AI mentor agent 405 can be or include at least one machine learning model or algorithm. For example, the computing system 105 can build, generate, or construct at least one AI mentor agent 405 by training one or multiple different machine learning models using a machine learning technique. For example, the computing system 105 can collect or record data of various expert medical practitioners and train the machine learning models of the AI mentor agent 405 based on the recorded sessions of the expert medical practitioners. Because the simulated environment 415 can be dynamic and not static, the manipulations and actions of a practicing surgeon in the simulated environment 415 can be determined by the trained AI mentor agent 405. The computing system 105 can train at least one model of the AI agent using at least one machine learning technique and the data of the procedures performed by the at least one expert surgeon. For example, the computing system 105 can perform a training technique. For example, the computing system 105 can execute a machine learning algorithm, such as gradient descent of losses or stochastic gradient descent of the losses with respect to parameters of a model of the AI mentor agent 405. The machine learning algorithm can implement second order gradient descent, newton method, conjugate gradient, quasi-newton method, or Levenberg-Marquardt algorithm to train the AI mentor agent 405.

For example, the computing system 105 can generate a training dataset based on the various recorded medical procedures. The computing system 105 can build the training dataset by extracting various pieces of information of the simulated environments 415 that the AI mentor agent 405 can sense, such as anatomical structure state, anatomical structure position, positions of the instruments, etc. and adding the pieces of information as input values for training the machine learning model. Furthermore, the computing system 105 can extract the various decisions or control actions made by expert surgeons for the various environmental situations. For example, the control actions can be various movements or trajectories that the instruments or endoscopes take. The control actions can be the orientations of the instruments, or activates or deactivations of instruments, opening or closing tips of instruments, etc. The AI mentor agent 405 can be generated or trained using the training dataset and at least one or multiple training techniques. The AI mentor agent 405 can be or include a world model that can simulate actions with an internal model to determine what actions to take within the simulated environment 415. The AI mentor agent 405 can include at least one or multiple deep learning models, convolutional neural networks, recurrent neural networks, deep learning agents, etc.

The constructed AI mentor agent 405 can be generated to perform a simulated medical procedure in the simulated environment 415 to perform a simulated medical procedure on a 3D anatomical structure in the simulated environment 415. The simulator 410 can provide the simulated environment 415 to the AI mentor 405 to execute on. The AI mentor agent 405 can generate control decisions for the various instruments of the medical robotic system 110 using the simulated environment 415, and send the control actions back to the simulator 410. The simulator 410 can animate at least one instrument or endoscope using the control decisions received from the AI mentor agent 405. For example, if the control decision is to rotate an instrument and move the instrument in a particular pattern to form an incision in an anatomical structure, the simulator 410 can animate the instrument rotating and moving in the particular pattern to form the incision. The virtual instruments and endoscopes controlled by the AI mentor agent 405 in the simulated environment 415 can be separate or different from the virtual instruments or endoscopes in the simulated environment 415 controlled by the operator of the medical robotic system 110. Furthermore, the instruments or endoscopes controlled by the AI mentor agent 405 can be semi-transparent, such that they do not fully occlude the scene or objects in the simulated environment 415. In this regard, a practicing surgeon performing a medical procedure in the simulated environment 415 can perform the procedure along with the AI mentor agent 405 or in parallel to the AI mentor agent 405 performing the same simulated medical procedure. As a surgeon performs a medical procedure, the surgeon can compare their own performance against the simulated expert's performance performed by the AI mentor agent 405, allowing the surgeon to focus on their areas where improvement is needed.

The AI mentor agent 405 can provide mentorship to trainees. For example, because the AI mentor agent 405 can be trained using data of expert surgeons, the AI mentor agent 405 can be generated to simulate the actions, attention, and decision making processes of expert surgeons. The trainee operators can practice alongside the AI mentor agent 405, e.g., view the movements of instruments controlled by the AI mentor agent 405 while they move their own simulated instruments in the simulated environment 415. In this regard, the AI mentor agent 405 can provide real-time guidance on the hand movements or decision making sequences of expert surgeons while the trainee attempts to perform the medical procedure themselves. Furthermore, the AI mentor 405 can generate focal points in the simulated environment 415. For example, the AI mentor agent 405 can be trained based on eye tracking data 445 of expert surgeons. In this regard, the AI mentor agent 405 can identify areas of interest of expert surgeons, e.g., locations or points in the simulated environment 415 where an expert surgeon would look. The simulator 410 can display indicators (such as a flashing point or star) in the simulated environment 415 to indicate what areas of interest the operator of the medical robotic system 110 should look at in real-time as the operator performs the simulated medical procedure.

In some embodiments, the computing system 105 can generate multiple different AI mentor agents 405. Furthermore, the computing system 105 can execute the AI mentor agents 405 together or in parallel, and animate the various decisions and actions of the different AI mentor agents 405 simultaneously or one at a time. In this regard, the computing system 105 can construct different AI mentor agents 405 for various expert surgeons or different hospitals. For example, the computing system 105 can train one AI mentor agent 405 for each of multiple different expert surgeons using training data of each individual expert surgeon. Similarly, the computing system 105 can generate an AI mentor agent 405 for a particular hospital (e.g., based on recorded training data for expert surgeons at the particular hospital). In some implementations, a user can select between different AI mentor agents 405 to display control actions within the simulated environment 415. By allowing a user to view the different decisions or techniques of the different AI mentor agents 405, the operator can view differing opinions on which techniques may lead to better outcomes.

The computing system 105 can activate or deactivate the AI mentor agents 405 at different times. For example, the simulator 410 may only cause data or visual artifacts generated by the AI mentor agent 405 to be displayed responsive to a user request provided via the client device 130 or the medial robotic system 110. For example, a user can press a button or interact with a button within the user interface 420 or on a display of the client 130 to trigger the AI mentor agent 405 to provide advice or suggested actions. Furthermore, the AI mentor agent 405 may only display information to the user responsive to the user asking a question or query 115, such as a question in a natural language, such as “what should I do next?” or “what should I have done to avoid that error?” Similarly, the AI mentor agent 405 can be triggered responsive to the computing system 105 detecting an error, such as excessive bleeding, tissue becoming damaged that should not have been damaged, etc. Responsive to a question, the AI mentor agent 405 can cause the AI mentor agent 405 to execute to answer the question by illustrating the next step to perform in the simulated environment 415 by animating the movements of the instruments in the simulated environment 415. Furthermore, the simulator 410 can back up the simulation to a point before the operator of the medical robotic system 110 made an error. The simulator 410 can then cause the AI mentor agent 405 to execute to illustrate the techniques recommended for avoiding the error.

Furthermore, the prompt constructor 135 can receive the query 115 and submit a prompt 160 to the generative model 165 to generate a response 170. The prompt constructor 135 can generate the prompt 160 based at least in part on the simulated environment 415. For example, the prompt constructor 135 can generate the prompt 160 to include some or all of the data of the simulated environment 415. The prompt constructor 135 can further query the data repository 140 for information, such as related medical procedure videos 150, kinematics data 155, or medical resources 145. The prompt constructor 135 can submit the prompt 160 to the generative model 165 to create a response 170, which can be returned to the client device 130 or to the medical robotic system 110. For example, if the query 115 was “what should I have done to avoid that error?” the generative model 165 can return a response 170 such as “You should have used firefly to verify that you had clipped the cystic bile duct before proceeding.” The AI mentor agent 405 can be triggered to execute along with the response 170 being displayed to the operator, such that the operator can see and watch the AI mentor agent 405 perform the medical procedure in a manner to avoid the error.

In some embodiments, the bot service 195 can generate queries 115 that users are likely to ask during the simulated surgery in the simulated environment 415. The prompt constructor 135 can retrieve portions of resources from the data repository 140. The prompt constructor 135 can construct a prompt 160 for each of queries 115, and submit the prompts 160 to the generative model 165. The generative model 165 can provide responses 170 including citations to the resources. The prompt constructor 135 can cause the queries 115 and the responses 170 to be transmitted and displayed on the client device 130 or the user interface 420.

Furthermore, in some embodiments, the computer system 105 can generate the AI mentor agent 405 when the anatomical structure being operated on is static or not moving. For example, the simulator 410 can detect whether an anatomical structure of the simulated environment 415 is being depressed by a surgical instrument, or is moving or changing shape. If the anatomical structure is not being depressed, is not moving, or has a static shape, the simulator 410 can trigger the AI mentor agent 405 to execute and simulate actions in the simulated environment 415.

In some embodiments, the computing system 105 can execute the AI mentor agent 405 to break down individual steps of a medical procedure. For example, the simulator 410 can animate the surgical actions of the AI mentor agent 405 for each individual step. The simulator 410 can display each step one by one or in turn. The simulator 410 can display the virtual instrument's movements or motions within the simulated environment 415 overlaid or within the same simulated environment 415 that the operator is performing the simulated medical procedure is. Alternatively, the simulator 410 can generate a picture-in-picture view. The simulator 410 can generate a window through which to view a version of the simulated environment 415 and virtual instruments manipulated by the AI mentor agent 405 to perform a particular step of the simulated medical procedure. The window of the AI mentor agent can be displayed within a larger window through which the operator views the simulated environment 415. The simulator 410 can cause the AI mentor agent 405 to simulate and display the next surgical actions to perform each time an operator completes aa surgical action or step in the simulated environment 415. The steps performed by the AI mentor agent 405 can adapted based on the existing anatomical structure in the simulated environment 415 after the user manipulates the anatomical structure in the simulated environment 415. In this regard, the simulation performed by the AI mentor agent 405 can consistently update given how the training surgeon has progressed (e.g., if the surgeon has tied their initial sutures with too long or too short tail, the AI mentor agent 405 can update the instructions of the AI mentor agent 405 to include getting another suture).

In some embodiments, instead of, or in addition to animating motions of semi-translucent surgical instruments controlled by the AI mentor agent 405, the simulator 410 can generate illuminated or marked areas in the simulated environment 415 based on the decisions of the AI mentor agent 405. For example, if the AI mentor agent 405 determines to make an incision or dissection along a particular path on the surface of an anatomical structure, the simulator 410 can display highlighting along the path or display a dotted line along the path on the surface of the virtual anatomical structure. In this regard, an operator of the medical robotic system 110 can follow the highlighting or dotted line when making an incision. Similarly, the simulator 410 can receive an indication from the AI mentor agent 405 where a suture would be applied along the dissection line, and a pair of illuminated or flashing points or colors can be displayed on the virtual tissue indicating where the AI mentor agent 405 suggests applying the suture.

In some embodiments, the simulator 410 can receive a path, movement, or trajectory that the AI mentor agent 405 recommends moving an instrument along to perform a particular action of the simulated procedure in the simulated environment 415. The simulator 410 can guide the user to control the simulated instrument in the simulated environment 415 along the same or a similar path as recommended by the AI mentor agent 405. For example, the simulator 410 can cause the input controls 430 to provide kinesthetic haptic feedback to provide a guide, guardrail, or bound to assist an operator to follow the recommended path to move an instrument. For example, the input controls 430 of the medical robotic system 110 can include haptic feedback, e.g., one or more motors that can operate to cause haptics (such as vibrations or force feedback) in the input controls 430. For example, if an operator moves a simulated instrument at least a predefined distance from the path recommended by the AI mentor agent 405, the simulator 410 can cause the input controls 430 to provide haptic feedback to the operator. The haptic feedback can notify the operator that they are veering off the path recommended by the AI mentor agent 405. The simulator 410 can cause the input controls 430 to provide a level of haptics corresponding to the deviation from the recommended path. For example, the farther the operator veers the virtual instrument from the path, the simulator 410 can cause the input controls 430 to provide higher levels of feedback haptics.

The input controls 430 can include force feedback. For example, the input controls 430 can include at least one motor that can move the input controls 430. The simulator 410 can cause the input controls 430 to use force feedback to guide the user to move the simulated instruments in the simulated environment 415 along the path recommended by the AI mentor agent 405. The simulator 410 can generate force feedback to create a gravity well to push the operator to move the simulated instruments in the simulated environment 415 along the path recommended by the AI mentor agent 405. For example, the AI mentor 405 can generate a trajectory or path along which to make an incision with a scalpel instrument. The simulator 410 can cause the input controls 430 to provide haptic feedback or force feedback to guide the operator of the medical robotic system 110 to move a simulated scalpel instrument in the simulated environment 415 along the trajectory or path recommended by the AI mentor agent 405.

In some embodiments, the simulator 410 can operate in a training mode where the simulator 410 causes the input controls 430 to generate force feedback to push the input controls 430 away from the recommended movement of the simulated instrument in the simulated environment 415. In this regard, the user may have to fight against or work against the force feedback of the input controls 430 to move the simulated instruments along the recommended path. The simulator 410 can cause the input controls 430 to provide error amplification, for example, if the operator strays from the recommended path, the simulator 410 can cause the input controls 430 to provide force feedback to push the simulated instrument away from the recommended path or resist the operator moving the simulated instrument back onto the recommended path. This can artificially increase the precision an operator needs during training.

In some embodiments, the AI mentor agent 405 can determine what type of visual cue, haptic feedback, force feedback, etc. to provide to the operator of the medical robotic system 110 to assist the user in training in the simulated environment 415. The AI mentor agent 405 can receive performance data via the feedback system 460 to identify what types of feedback or visual cues help the operator learn. The AI mentor agent 405 can recommend or implement the visual cues or feedback types that best help the operator learn. Furthermore, as new types of hardware feedback in the input control 430 becomes available, or software updates with new types of visual cues become available, the AI mentor agent 405 can recommend or implement the new types of feedback or visual cues as they become available. In this regard, the AI mentor agent 405 can update itself as well to evaluate its own ability to train operators of the medical robotic system 110. New types of communication and cues may be generated, implemented, and assessed by AI mentors themselves based on what is guiding surgeons to better performance utilizing their pre-training and post-training data. The AI mentor agents 405 can self-assess and improve the kinds of guidance the AI mentor agents 405 provide. The AI mentor agents 405 can assess surgical performance from a large set of high-dimensional data.

In some embodiments, the computing system 105 can generate at least one AI mentee agent 465. The AI mentee agent 465 can be or include an application, an executable, a script, a set of instructions, etc. The AI mentee agent 465 can be similar to the AI mentor agent 405, but trained on a different data set. The AI mentee agent 465 can perform similar, or the same functions as the AI mentor agent 405. The AI mentee agent 465 can be an intelligent agent (IA) that can perceive an environment (e.g., the simulated environment 415) and take actions in the simulated environment 415 (e.g., perform surgery with the simulated instruments in the simulated environment 415). For example, the AI mentee agent 465 can simulate the behaviors of the various trainees operating the medical robotic system 110 to perform medical procedures in the simulated environment 415 based on data from the simulated sessions (e.g., eye tracking data 445, kinematic data 455, etc.). The AI mentee agent 465 can include at least one or multiple deep learning models, convolutional neural networks, recurrent neural networks, deep learning agents, etc.

The AI mentee agents 465 can be generated from data collected from operators training in the simulated environment 415. The AI mentee agents 465 can be generated, constructed, or built to mimic the trainee operators who practice in the simulated environment 415. The AI mentee agents 465 can perform simulated procedures in the simulated environment 415. The AI mentee agents 465 can generate questions or queries 115. The simulator 410 can display the queries 115 on the user interface 420 or the client device 130. Furthermore, the prompt constructor 135 can generate a prompt 160 using the query submitted by the AI mentee agent 465, and submit the response to the generative model 165 to produce the response 170. The computing system 105 can cause the response 170 to be displayed along with the query 115 on the user interface 420 or the client device 130.

In some embodiments, the AI mentee agent 465 can perform a simulated medical procedure in the simulated environment 415 while the operator observes or performs their own medical procedure in the simulated environment 415. The AI mentee agent 465 can prompt the operator to provide feedback on the simulated procedure performed by the AI mentee agent 465. For example, the AI mentee agent 465 can cause the simulator 410 to display a prompt within the user interface 420 or on the client device 130 asking for the operator's feedback. The operator can input text based feedback via the medical robotic system 110 or the client device 130. The AI mentee agent 465 can use the operator's feedback to train or adapt the AI mentee agent 465. This can provide the operator with opportunities to improve their ability to teach and reflect on what makes the procedure go well.

The computing system 105 can include at least one anatomy model generator 470. The anatomy model generator 470 can generate models for full or partial procedure simulations by generating detailed 3D anatomical models. The anatomy model generator 470 can randomize the models for general practice or tailor the models to reflect specific patient cases. The anatomy model generator 470 can generate anatomical structures for the simulated environment 415. The anatomy model generator 470 can generate at least one model (such as a three dimensional (3D) model) of an anatomical structure, such as a mesh and texture file. The anatomy model generator 470 can generate a model of the anatomical structure, such as a model of a heart, a model of a pancreas, a model of a knee, a model of a tendon, a model of a leg to a patient, etc. The anatomy model generator 470 can generate anatomical models for the simulated environment 415 pseudo-randomly. For example, the anatomy model generator 470 can store base models of various anatomical structures. The anatomy model generator 470 can store parameterized models. The anatomy model generator 470 can store abnormalities for various anatomical structures. For example, the anatomical structures can be defined by various adjustable parameters, settings, or attributes such as fat content, muscle size, limb length, limb width, blood coagulation level, etc. For example, the anatomical structure can be defined with anatomical abnormalities, such as aberrant ducts, heart defects, supernumery organs, varying vasculature, etc. Each or some of the parameters or attributes can have value ranges of acceptable parameter values.

The anatomy model generator 470 can dynamically generate anatomical structures by randomizing the parameters or attributes of various anatomical structures. The anatomy model generator 470 can generate a pseudo-random value for each parameter or attribute of a particular anatomical model within the range of acceptable parameter values or attribute values. In some embodiments, the anatomy model generator 470 can display the parameters or attributes for the anatomical structure to a user on the user interface 420 or on the client device 130. The anatomy model generator 470 can display the parameters or attributes as graphic elements, e.g., sliders, input windows, input elements, etc. Via the graphic elements, the anatomy model generator 470 can receive values for customizing the anatomical structure. Based on the randomized or user selected parameters, attributes, or abnormality values, the anatomy model generator 470 can generate the anatomical model for the simulator 410 to render and simulate in the simulated environment 415.

In some embodiments, the anatomy model generator 470 can generate an anatomical structure to match a patient's anatomy, e.g., based on real-patient data. For example, if an operator has an upcoming medical procedure to perform on an anatomical structure of a real surgeon, the operator can first practice the procedure in a simulated environment 415. In this regard, the anatomy model generator 470 can receive data indicating an anatomical structure of a real patient. For example, the anatomy model generator 470 can receive a computed tomography (CT) scan or receive endoscope data of another medical procedure performed on the anatomical structure. The anatomy model generator 470 can generate an anatomical model using the CT scan or endoscope data. In this regard, an operator can practice for an upcoming procedure or review a past case with precision.

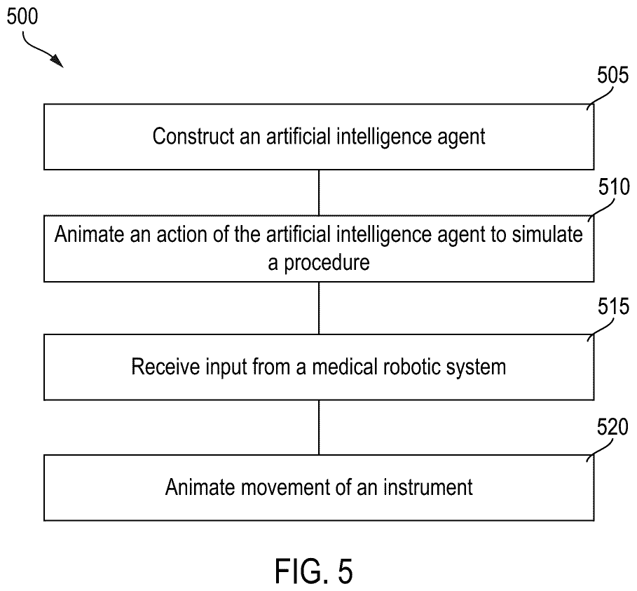

Referring now to FIG. 5, among others, an example method 500 of simulating a medical procedure, the simulation including an AI mentor agent 405, is shown. At least a portion of the method 500 can be performed by the computing system 105, the client device 130, the medical robotic system 110, or any other component or component thereof. The method 500 can include an ACT 505 of constructing an AI agent. The method 500 can include an ACT 510 of animating an action of the AI agent to simulate a procedure. The method 500 can include an ACT 515 of receiving input from a medical robotic system. The method 500 can include an ACT 520 of animating movement of an instrument.

At ACT 505, the method 500 can include constructing, by the computing system 105, an AI agent, e.g., an AI mentor agent 405 or an AI mentee agent 465. Constructing an AI agent can include generating or training at least one or multiple models making up an AI agent. For example, the method 500 can include collecting or assembling training data to train one or multiple models of the AI mentor agent 405 or the AI mentee agent 465. For example, the method 500 can include collecting expert surgeon data of various medical procedures performed by expert surgeons. The expert surgeon data can be data collected for real medical procedures performed by an expert surgeon, or simulated medical procedures performed by the expert surgeon. The data can include endoscope data, kinematics data 455, eye tracking data 445, etc. The method 500 can include executing at least one machine learning training algorithm to train at least one model of the AI mentor agent 405 using the expert surgeon data.

The method 500 can include collecting trainee data of various medical procedures performed by trainees, e.g., operators of the medical robotic system 110 who are still learning or improving their skills or are otherwise not expert surgeons. The trainee data can be data collected for real medical procedures performed by a trainee surgeon, or simulated medical procedures performed by the trainee surgeon. The data can include endoscope data, kinematics data 455, eye tracking data 445, etc. The method 500 can include executing at least one machine learning training algorithm to train at least one model of the AI mentee agent 465 using the trainee surgeon data.

At ACT 510, the method 500 can include animating, by the computing system 105, an action of the AI agent to simulate a procedure. The method 500 can include executing an AI agent (e.g., the AI mentor agent 405 or the AI mentee agent 465) on the simulated environment 415 to determine at least one or multiple actions. The method 500 can include executing the AI agent using the simulated environment 415 as an input. For example, the AI agent can sense various pieces of information of the simulated environment 415, such as the size, shape, state, or location of an anatomical structure that the medical procedure is performed on. The AI agent can execute on the entire simulated environment 415, or a portion of a simulated environment 415. The AI agent can generate or determine an action to perform in the simulated environment 415. For example, the action can be a determination to make an incision on an anatomical structure, a determination to cauterize a cut on an anatomical structure, a determination to suture an incision, etc. The AI agent can generate a movement, a path, or a trajectory for the instrument of the medical robotic system 110 to travel on to complete the action. The AI agent can determine various rotations of the instrument along the movement, path, or trajectory.

The simulator 410 can render or animate movement of a virtual instrument in the simulated environment 415 based on the action determined by the AI agent. For example, the simulator 410 can generate a virtual instrument in the simulated environment 415, and then move, manipulate, or rotate the virtual instrument based on the determined action of the AI agent. The simulator 410 can cause the virtual instrument animated semi-translucently so that an operator can see at least partially through the virtual instrument. In some embodiments, instead of or in addition to animating the movements of a virtual instrument in the simulated environment 415, the simulator 410 can render depictions of the actions of the AI agent in the simulated environment 415. For example, the simulator 410 could render a dashed line on an anatomical structure indicating where an operator should make an incision. For example, the simulator 410 can render a circle or star at a portion where a suture should be sewn.

At ACT 515, the method 500 can include receiving, by the computing system 105, input from a medical robotic system 110. For example, the operator can provide user input via the input controls 430. The input control 430 can produce instrument control signals 425. The instrument control 425 can be command signals to move an instrument or endoscope up or down along z-axis, left or right along a y-axis, forward or back along an x-axis. Furthermore, the input control 430 can rotate the instrument about each axis. The instrument control 425 can further include input to open or close an instrument such as a scissors. The instrument control 425 can further include activating or deactivating an electrical instrument to cauterize tissue.

At ACT 520, the method 500 can include animating, by the computing system 105, movement of an instrument. The method 500 can include animating a virtual instrument in the simulated environment 415 based on the instrument control 425. For example, the method 500 can include animating the movement or motion of the virtual instrument according to the movement indicated by the instrument control 425 provided by the input controls 430. For example, the simulator 410 can animate movement of the virtual instrument in the simulated environment 415 along an x, y, or z axis of a body of the virtual instrument or an x, y, or z axis of the simulated environment 415 itself based on the instrument control 425 commanding movement of the simulated environment along the x, y, or z axis of a body of the virtual instrument or an x, y, or z axis of the simulated environment 415.

The method 500 can include animating movement of a virtual instrument in the simulated environment 415 interacting with anatomical structures in the simulated environment. For example, the method 500 can include simulating the physics of an anatomical structure, such that the simulated instrument can make an incision in the anatomical structure, grasp and move the anatomical structure, irrigate the anatomical structure, suture the anatomical structure, cauterize the anatomical structure, etc. In this regard, as the user provides instrument control 425 via the input controls 430 to manipulate the virtual instrument in the simulated environment 415 to perform a medical procedure, the user can simultaneously view the decisions of the AI mentor agent 405 in the simulated environment 415 animated at ACT 510.

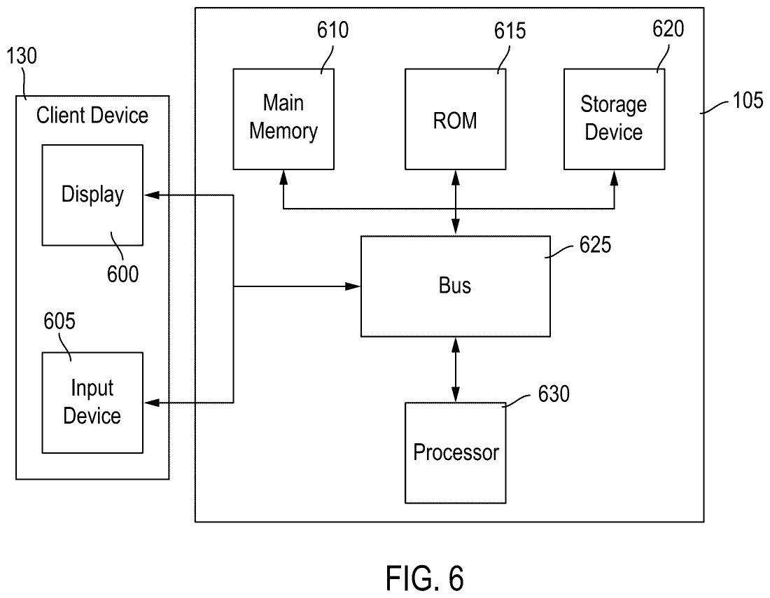

Referring now to FIG. 6, among others, an example block diagram of a computing system 105 is shown. The computing system 105 can include or be used to implement a data processing system or its components. The architecture described in FIG. 6 can be used to implement the computing system 105, the medical robotic system 110, or the client device 130. The computing system 105 can include at least one bus 625 or other communication component for communicating information and at least one processor 630 or processing circuit coupled to the bus 625 for processing information. The computing system 105 can include one or more processors 630 or processing circuits coupled to the bus 625 for processing information. The computing system 105 can include at least one main memory 610, such as a random access memory (RAM) or other dynamic storage device, coupled to the bus 625 for storing information, and instructions to be executed by the processor 630. The main memory 610 can be used for storing information during execution of instructions by the processor 630. The computing system 105 can further include at least one read only memory (ROM) 615 or other static storage device coupled to the bus 625 for storing static information and instructions for the processor 630. A storage device 620, such as a solid state device, magnetic disk or optical disk, can be coupled to the bus 625 to persistently store information and instructions.

The computing system 105 can be coupled via the bus 625 to a display 600, such as a liquid crystal display, or active matrix display. The display 600 can display information to a user. An input device 605, such as a keyboard or voice interface can be coupled to the bus 625 for communicating information and commands to the processor 630. The input device 605 can include a touch screen of the display 600. The input device 605 can include a cursor control, such as a mouse, a trackball, or cursor direction keys, for communicating direction information and command selections to the processor 630 and for controlling cursor movement on the display 600. The display 600 and the input device 605 can be a component of the client device 130 coupled with the computing system 105.

The processes, systems and methods described herein can be implemented by the computing system 105 in response to the processor 630 executing an arrangement of instructions contained in main memory 610. Such instructions can be read into main memory 610 from another computer-readable medium, such as the storage device 620. Execution of the arrangement of instructions contained in main memory 610 causes the computing system 105 to perform the illustrative processes described herein. One or more processors in a multi-processing arrangement can be employed to execute the instructions contained in main memory 610. Hard-wired circuitry can be used in place of or in combination with software instructions together with the systems and methods described herein. Systems and methods described herein are not limited to any specific combination of hardware circuitry and software.

Although an example computing system has been described in FIG. 6, the subject matter including the operations described in this specification can be implemented in other types of digital electronic circuitry, or in computer software, firmware, or hardware, including the structures disclosed in this specification and their structural equivalents, or in combinations of one or more of them.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer based components.

The systems described above can provide multiple ones of any or each of those components and these components can be provided on either a standalone system or on multiple instantiations in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C#, PROLOG, Python, or in any byte code language such as JAVA. The software programs or executable instructions can be stored on or in one or more articles of manufacture as object code.

Example E and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices including cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. ACTs, elements and features discussed in connection with one implementation are not intended to be excluded from a similar role in other implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any ACT or element being based on any information, act or element may include implementations where the act or element is based at least in part on any information, act, or element.

Any implementation disclosed herein may be combined with any other implementation or example, and references to “an implementation,” “some implementations,” “one implementation” or the like are not necessarily mutually exclusive and are intended to indicate that a particular feature, structure, or characteristic described in connection with the implementation may be included in at least one implementation or example. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B”’ can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

What is claimed is:

1. A system, comprising:
one or more processors, coupled with memory, to:
construct an artificial intelligence agent using data of medical procedures performed by at least one medical practitioner, the artificial intelligence agent to perform a simulated medical procedure on a three dimensional anatomical structure;
animate, on a user interface, at least one action of the artificial intelligence agent in a simulated medical environment to perform the simulated medical procedure on the three dimensional anatomical structure;
receive an input from a medical robotic system to manipulate an instrument in the simulated medical environment; and
animate, on the user interface with the animated at least one action, movement of the instrument within the simulated medical environment based on the input received from the medical robotic system.

2. The system of claim 1, wherein the one or more processors are further configured to:
receive historical performance indicators of an operator of the medical robotic system;
generate a training pathway for the operator using the historical performance indicators, the training pathway comprising a series of tasks for the operator to perform in simulations;
identify a task of the series of tasks for the operator to perform; and
generate an interactive simulation for the operator of the medical robotic system to perform to complete the task.

3. The system of claim 1, wherein the one or more processors are further configured to:
train at least one model of the artificial intelligence agent using at least one machine learning technique and the data of the medical procedures performed by the at least one medical practitioner, the model to determine the at least one action;
receive data describing the three dimensional anatomical structure; and
execute the model of the artificial intelligence agent using the data describing the three dimensional anatomical structure to determine the at least one action.

4. The system of claim 1, wherein the one or more processors are further configured to:
receive data indicating movement of an eye of the at least one medical practitioner during at least one medical procedure;
generate, using the data indicating movement of the eye of the at least one medical practitioner, a heatmap comprising a plurality of points and corresponding levels, the corresponding levels indicating lengths of time the medical practitioner looked at the plurality of points;
receive data indicating movement of an eye of an operator of the medical robotic system; and
cause the user interface to display the heatmap and the movement of eye of the operator on the heatmap.

5. The system of claim 1, wherein the one or more processors are further configured to:
generate at least one performance metric based on the data of the at least one medical practitioner;
generate, based on the input received from the medical robotic system, at least one performance metric for an operator of the medical robotic system; and
cause the user interface to display data based on a comparison of the at least one performance metric of the at least one medical practitioner to the at least one performance metric of the operator.

6. The system of claim 1, wherein the one or more processors are further configured to:
receive performance results of a plurality of simulated medical procedures of a plurality of different types performed by an operator of the medical robotic system;
identify, based on the performance results, a performance issue for a type of medical procedure of the plurality of different types of medical procedures; and
generate the medical environment and the three dimensional anatomical structure based on the performance issue.

7. The system of claim 1, wherein the one or more processors are further configured to:
generate pseudo-random values for a plurality of attributes defining the three dimensional anatomical structure; and
generate the three dimensional anatomical structure based on the pseudo-random values for the plurality of attributes.

8. The system of claim 1, wherein the one or more processors are further configured to:
receive user defined values via the user interface for a plurality of attributes defining the three dimensional anatomical structure; and
generate the three dimensional anatomical structure based on the user defined values for the plurality of attributes.

9. The system of claim 1, comprising the one or more processors to:
receive a three dimensional scan of a physical anatomical structure; and
generate the three dimensional anatomical structure based on the three dimensional scan.

10. The system of claim 1, wherein the one or more processors are further configured to:
receive, via the user interface, a selection of an entire medical procedure to simulate, or a portion of the medical procedure to simulate; and
simulate the medical procedure based on the selection.

11. The system of claim 1, wherein the one or more processors are further configured to:
receive a query about the simulated medical procedure from a client device;
retrieve, using the query, one or more resources on medical procedures from a data repository;
construct a prompt based on the query, the simulated medical procedure, and the one or more resources;
provide the prompt to a generative model to generate a response to the query, the response comprising a citation to a resource of the one or more resources; and
transmit the response to the client device.

12. The system of claim 1, wherein the one or more processors are further configured to:
execute a generative model to predict a plurality of queries comprising questions users are likely to ask during the simulated medical procedure;
retrieve, using the queries, portions of resources on the medical procedures from a data repository;
execute the generative model using the queries, the simulated medical procedure, and the portions of the resources to generate responses to the queries, the responses comprising citations to the resources; and
transmit the queries and the responses to a client device to display in a graphical user interface on the client device.

13. A method, comprising:
constructing, by one or more processors, coupled with memory, an artificial intelligence agent using data of medical procedures performed by at least one medical practitioner, the artificial intelligence agent to perform a simulated medical procedure on a three dimensional anatomical structure;
animating, by the one or more processors, on a user interface, at least one action of the artificial intelligence agent in a simulated medical environment to perform the simulated medical procedure on the three dimensional anatomical structure;
receiving, by the one or more processors, an input from a medical robotic system to manipulate an instrument in the simulated medical environment; and
animating, on the user interface with the animated at least one action, by the one or more processors, movement of the instrument within the simulated medical environment based on the input received from the medical robotic system.

14. The method of claim 13, method:
receiving, by the one or more processors, historical performance indicators of an operator of the medical robotic system;
generating, by the one or more processors, a training pathway for the operator using the historical performance indicators, the training pathway comprising a series of tasks for the operator to perform in simulations;
identifying, by the one or more processors, a task of the series of tasks for the operator to perform; and
generating, by the one or more processors, an interactive simulation for the operator of the medical robotic system to perform to complete the task.

15. The method of claim 13, comprising:
training, by the one or more processors, at least one model of the artificial intelligence agent using at least one machine learning technique and the data of the medical procedures performed by the at least one medical practitioner, the model to determine the at least one action;
receiving, by the one or more processors, data describing the three dimensional anatomical structure; and
executing, by the one or more processors, the model of the artificial intelligence agent using the data describing the three dimensional anatomical structure to determine the at least one action.

16. The method of claim 13, comprising:
receiving, by the one or more processors, data indicating movement of an eye of the at least one medical practitioner during at least one medical procedure;
generating, by the one or more processors, using the data indicating movement of the eye of the at least one medical practitioner, a heatmap comprising a plurality of points and corresponding levels, the corresponding levels indicating lengths of time the medical practitioner looked at the plurality of points;
receiving, by the one or more processors, data indicating movement of an eye of an operator of the medical robotic system; and
causing, by the one or more processors, the user interface to display the heatmap and the movement of eye of the operator on the heatmap.

17. The method of claim 13, comprising:
generating, by the one or more processors, at least one performance metric based on the data of the at least one medical practitioner;
generating, by the one or more processors, based on the input received from the medical robotic system, at least one performance metric for an operator of the medical robotic system; and
causing, by the one or more processors, the user interface to display data based on a comparison of the at least one performance metric of the at least one medical practitioner to the at least one performance metric of the operator.

18. The method of claim 13, comprising:
receiving, by the one or more processors, performance results of a plurality of simulated medical procedures of a plurality of different types performed by an operator of the medical robotic system;
identifying, by the one or more processors, based on the performance results, a performance issue for a type of medical procedure of the plurality of different types of medical procedures; and
generating, by the one or more processors, the medical environment and the three dimensional anatomical structure based on the performance issue.

19. A non-transitory computer-readable medium storing processor-executable instructions that, when executed by one or more processors, cause the one or more processors to:
construct an artificial intelligence agent using data of medical procedures performed by at least one medical practitioner, the artificial intelligence agent to perform a simulated medical procedure on a three dimensional anatomical structure;
animate, on a user interface, at least one action of the artificial intelligence agent in a simulated medical environment to perform the simulated medical procedure on the three dimensional anatomical structure;
receive an input from a medical robotic system to manipulate an instrument in the simulated medical environment; and
animate, on the user interface with the animated at least one action, movement of the instrument within the simulated medical environment based on the input received from the medical robotic system.

20. The non-transitory computer-readable medium of claim 19, wherein the processor-executable instructions further include instructions to cause the one or more processors to:
receive data indicating movement of an eye of the at least one medical practitioner during at least one medical procedure;
generate, using the data indicating movement of the eye of the at least one medical practitioner, a heatmap comprising a plurality of points and corresponding levels, the corresponding levels indicating lengths of time the medical practitioner looked at the plurality of points;
receive data indicating movement of an eye of an operator of the medical robotic system; and
cause the user interface to display the heatmap and the movement of eye of the operator on the heatmap.
